(19) United States
(12) Patent Application Publication
(10) Pub. No.: US 2018/0266637 A1
(43) Pub. Date: Sep. 20, 2018

(54) DIRECT CURRENT HYBRID LIGHTING AND ENERGY MANAGEMENT SYSTEMS AND METHODS

(71) Applicant: CLEANTEK Industries Inc., Rockyview (CA)

(72) Inventors: Joshua CURLETT, Calgary (CA); Charles K. TIMBREZA, Austin, TX (US)

(21) Appl. No.: 15/754,793

(22) PCT Filed: Aug. 24, 2016
(86) PCT No.: PCT/CA2016/050996

§ 371 Date: Feb. 23, 2018

Related U.S. Application Data
(60) Provisional application No. 62/209,248, filed on Aug. 24, 2015.

(51) Int. Cl. F21L 13/06; H02J 7/00; H02K 7/18; H02J 7/35; F21L 4/02; G01R 31/36; H01M 10/0525; H01M 10/44; H01M 2/02; H01M 2/26; H01M 10/615; H01M 10/6554; H01M 10/657; H01M 10/42; F02B 63/04

(52) U.S. Cl. CPC F21L 13/06; F21V 21/22; H02J 7/0029; H02K 7/183; H02J 7/35; F21L 4/02; G01R 31/3658; H01M 10/0525; H01M 10/44; H01M 2/028; H01M 2/26; H01M 10/615; H01M 10/6554; H01M 10/657; H01M 10/425; F02B 63/048; H02J 2007/0037; H02J 7/0068

(57) ABSTRACT

The invention relates to a portable, skid mounted, wheeled and/or collapsible hybrid-power lighting and energy management system for harsh, remote and/or high latitude locations. The system combines an internal combustion engine (ICE) power source with a direct current power generator and a battery storage system for providing power to light system. The system may also include an ICE heating system and/or renewable solar and/or wind power systems in a manner that improves efficiency and reliability of operation in such locations, while preserving and improving functionality of operation and significantly reducing operator interaction during set-up and operation.

### FIELD OF THE INVENTION

The invention relates to a portable, skid mounted, wheeled and/or collapsible hybrid-power lighting and energy management system for harsh, remote and/or high latitude locations. The system combines an internal combustion engine (ICE) power source, a direct current power generator and/or battery storage system for accepting power inputs and providing power to a light system and/or other loads as typically required. The system may also include any one or combination of control system, an ICE heating system, a battery heating system and/or a renewable energy system. The present invention is configured in a manner that improves efficiency and reliability of operation in such locations, while preserving ICE runtime and/or fuel consumption and improving functionality of operation and reducing operator interaction during set-up and operation. In one aspect of the invention, the system configuration and/or control system may allow an AC load, for example an external or ancillary AC load operatively connected to the system permanently or intermittently, to be powered at least in part by a renewable energy source. For clarity, this aspect of the present invention may permit an AC load to firstly draw its power from stored power in a battery bank, the stored power at least partially derived from solar, wind or other renewable. Further, when a particular AC load is below a threshold amount, this configuration may permit the powering of an AC load without having to run the ICE wherein the ICE need only be activated when the load is above a certain threshold or threshold timeframe. The latter has been a drawback to prior art configurations, control systems and teachings related to the present invention and/or field of invention which require the ICE to be running at all times when an AC load is required. Another aspect of the present invention allows the lighting system, which is the primary function of a remote and portable lighting system, to convert fossil fuel as a prime mover into light at an efficiency higher than any prior art system. Another aspect of the invention is the ability to locate itself, download data from a satellite, parse or otherwise convert that data into values representing sunrise and sunset times and use those values to automatically mirror the systems light on/off schedule to match local sunrise and sunset times. Another aspect of the invention allows work to be performed, whether light power or AC load power, by configuring the system components in a manner that reduces ICE runtime, conserves fossil fuel and permits an AC load access to renewables in remote or stranded locations.

### BACKGROUND OF THE INVENTION

Portable light towers have been used extensively for lighting of a wide range of locations including construction sites, oil and gas drilling sites, stadiums, mines, military zones and a large number of other locations and applications.

In cases where these systems are operated in remote locations, factors taken into account when deploying and operating such equipment may include:
a) the delivered cost of fuel;
b) the reliability of the fuel supply chain;
c) the cost of the equipment (e.g. rental or purchase costs);
d) the reliability of the equipment; and
e) the amount of manpower required.

For example, delivering fuel to a remote location substantially increases the cost of fuel often by several multiples as compared to deployment of the same equipment in a non-remote setting. As can be appreciated, the increase in delivery costs is due to increased equipment and personnel costs required to transport and deliver fuel to locations where it takes time and specialized equipment to get it to the remote location. Similarly, if the equipment can not be reliably used (e.g. because it breaks down, or because can only be used in certain circumstances such as when there is sufficient sun or the ambient temperature is within a certain range) the operator may choose a less efficient but more reliable alternative.

Historically, portable light towers have been powered by internal combustion engines (ICEs) that consume fuel to generate alternating current (AC) electricity to power the onboard AC powered lights and AC power receptacles on the light towers for supplying AC power from the ICE to the receptacles for distribution to an internal, external or ancillary load. Other prior art systems may use an ICE connected to an AC generator to provide AC power to AC to DC charge controllers which in turn supply a DC charge current to a battery bank which in turn supplies DC power to DC powered LED lights onboard the light tower. In both cases and in prior art the onboard AC receptacles derive their power from an AC generator operatively connected to the ICE. A drawback to the latter system is that the AC receptacle is not configured to the battery bank in a manner that allows the AC load to be powered or partially powered by the stored energy in a battery bank. This is an important drawback when the stored energy in the battery bank is at least partially derived from renewable energy inputs, such as a solar or wind or power grid input. Additionally, when a volume of fossil fuel is consumed as a prime mover input for an ICE, then converted into the mechanical energy provided by the ICE shaft, then converted from AC to DC when charging a battery storage system, there are significant losses in the form of heat energy at each stage of energy conversation plus there is mechanical usage waste of the ICE, both of which permit unwanted fossil fuel consumption and mechanical usage waste.

Additionally, the cost and operational oversight needed in these prior art systems is excessive in light of the present invention. It is desirable for a system that converts mechanical power directly into DC current for direct supply to a battery storage system and/or a lighting system and/or a control system as it reduces the system cost, complexity and fossil fuel consumption when compared to prior art systems. In particular, in prior art systems where AC auxiliary loads are powered by an AC generator driven by an engine, the engine must be running in order to power even the smallest of AC auxiliary loads.

Further, providing a DC to AC power inverter operatively connected between a battery bank and the AC receptacles make any renewable energy, from a renewable input such as solar, or grid power stored in a battery bank available to the AC receptacle. This configuration limits energy waste created by an onboard power inversion system, such as AC to DC battery charge controllers, to intermittent and/or non-existent externally applied AC loads only. Further, this configuration may help allow the lighting system, which is the prime function of a remote and portable lighting system, to have a higher energy consumption efficiency than a prior art system.

As a secondary function, these engine-powered light towers, in addition to providing nighttime lighting, may also be used to generate auxiliary power for other equipment at an off-grid location such as power tools and other electric loads requiring configured to be operable when powered by an AC power source.

Further, many of these prior art systems, the ICE-powered light towers are manually operated, requiring an operator to turn the system on and off as desired. In addition, with certain systems an operator will have to monitor and supply fuel, perform regular oil changes as well as other maintenance that will be required due to the high run times of the engine. Generally, the high engine run times are simply accepted in the industry as the cost of doing business in a remote location because there is no alternative.

The typical portable light tower of the prior art will include a trailer and/or frame for supporting an ICE and its associated fuel tank and one or more light standards that pivot with respect to the trailer for elevating one or more lighting fixtures above the ground. In the past, various types of incandescent bulbs (which can use the generated AC power directly) and/or LED lights have been the predominant type of lighting system used in such light towers.

As is known, in addition to the increased costs associated with operating equipment at a remote location, there are several other drawbacks with these lighting systems. These include:
noisy operation all night and any time AC power is required;
high fuel consumption;
long engine run-times;
inability to operate due to fuel shortages or delays;
impact of weather on refueling schedules in remote or high latitude locations;
high carbon footprint;
toxic emissions;
no controller, instead having only switches, toggles and buttons;
need for manually turning lights off and on each day;
if solar eyes (e.g. light sensors) are employed, unreliable light on and off function due to fog or ice buildup on lens and/or false light on/off due to various and changing ambient light levels in the area not related to sunrise or sunset;
engine service requirements particularly resulting from the high run time hours and/or operation in cold climates;
increased maintenance costs due to operation in a remote location;
inefficient operation particularly during cold weather where ICEs may need to be run during daylight hours to maintain ICE warmth to ensure nighttime reliability; and
high personnel costs due to the complexity of system set-up and the time required for manual operation and/or operator supervision.

In response to the fuel consumption, fuel costs and emissions drawbacks, attempts have been made to reduce the carbon footprint and fuel consumption of mobile lighting systems by employing the use of solar and/or wind power. However, on a practical scale such systems are generally unable to provide power sourced from a renewable such as solar to onboard AC receptacles (e.g. an auxiliary load drawing AC current such as power tools plugged into an external socket) which are commonly used in traditional ICE powered mobile lighting systems. Therefore the benefit of solar in the prior art systems has only been available to the lighting system or other loads which draw their power from the stored energy in the battery bank.

Further, in many cases there has been a desire for prior art solar powered lighting systems, which do not have an onboard ICE, to also provide auxiliary power. However, current solar systems have no ability to provide power for the operation of ancillary equipment. That is, even during long sunny summer days, due in part to the limited available space for solar panels on a mobile system, a light tower may only be able to absorb enough energy on a given day to supply the lighting for that night thus leaving little to no extra energy to power ancillary equipment. Thus, as light towers traditionally have the dual purpose of supplying power to the lighting fixture as well as supplying power and/or backup power to ancillary equipment, a significant drawback of solar and wind powered light towers is that they are limited to only lighting and only in certain geographic locations and only in certain environmental conditions. This drawback eliminates the ability of an operator to reduce their carbon footprint, because in order to do so they would have to sacrifice functionality provided by consuming fossil fuels by an ICE as a supplement to renewable energy inputs such as solar energy.

Specifically in harsh, remote and/or cold environments, solar and/or wind systems have not been capable of reliably supplying lighting systems for these environments. Further still, in the harsh environment of northern latitudes (e.g. northern Canada or Alaska), particularly during the winter season with reduced daylight hours, another operational issue is that such systems are often affected by reduced battery performance due to the cold, snow cover of solar panels and/or the risk of moving parts of a wind turbine (for example) becoming frozen. Use of stored power for heating devices within the system that may allow such systems to operate reliably in cold climates will almost always exceed the available power from renewable sources alone.

Another factor affecting the implementation of solar and/or wind-powered systems is the economics of utilizing new technology to reduce an operator's carbon footprint. While an operator may wish to reduce their carbon footprint, the cost of doing so in a meaningful way is generally prohibitive. For example, with current technology, an operator would have to invest in the purchase of both an ICE system in order to run ancillary equipment and/or to ensure the system will run reliably in the winter as well as a solar/wind system to try and reduce fuel cost and carbon footprint.

Cold temperatures can also adversely affect battery banks by decreasing the time period a battery can hold its charge and shortening the lifespan of the batteries. A desired operating temperature for a lead acid battery is generally 25° C. to 40° C., and for a lithium ion battery is 0° C. to 40° C. At −15° C., a typical deep-cycle absorbed glass mat (AGM) battery can lose 30-50% or more of its charge. This is important to note because when solar may already be limited due to solar panel footprint or environmental conditions, losses in the overall systems due to the cold effect on batteries (or other losses such as line losses, etc.) can void the benefit gained by solar input. Therefore, in keeping with the primary focus of the present invention which is to minimize or reduce electrical and thermal losses within the system in a manner that reduces combustion fuel required for operational needs, a continuing need remains to keep the batteries bank temperature controlled within an ideal range.

As a result, there has been a need to develop efficient portable lighting systems that are robust and inexpensive and allow the ICE run-time to be reduced. In particular, simplifying the electronics of the lighting systems whist maintaining or improving functionality may be advantageous. Furthermore, there is a need to develop portable lighting systems which are better able to use energy from multiple sources (e.g. renewable and non-renewable energy systems). Additionally, there is a need to improve on prior art systems that utilize renewables in conjunction with an ICE in a manner that creates increased efficiencies when converting fossil fuels into light and/or reduce fossil fuels when powering AC or external loads.

US2012/0206087A1; US2012/0201016A1; US2010/0232148A1; and U.S. Pat. No. 7,988,320 are examples of solar-powered lights and U.S. Pat. Nos. 6,805,462B1; 5,806,963 are examples of traditional ICE towers. U.S. Pat. No. 8,350,482; US2010/0220467; and US2009/0268441 are examples of non-portable hybrid lighting devices that utilize both solar and wind energy. U.S. Pat. No. 7,988,320, US2010/0236160 and U.S. Pat. No. 8,371,074 teach wind masts that can be lowered to the ground. U.S. Pat. No. 5,003,941; US2012/0301755 and US2006/0272605 teach systems for heating engines and/or batteries. U.S. Pat. No. 7,781,902 teaches a generator set including an internal combustion engine which powers a generator configured to produce DC (e.g. AC alternator with an rectifier) and a battery configured to power an external load via an inverter.

Applicant's Canadian patent 2,851,391 and related co-pending applications based on PCT/CA2013/000865 also relate to a portable hybrid-power lighting and energy management systems and are incorporated herein by reference in their entirety.

One drawback to embodiments of the technology described in Canadian patent 2,851,391 include cost and complexity related to managing AC power from an AC generator though a bank of AC-DC charge controllers for distributing into a DC battery bank and/or DC powered lights. As is known, lighting systems such as these are primarily used in off-grid applications and as such are subject to poor road conditions during transport. These conditions result in vibrational shock to equipment and their components resulting is damage. The inventors have realized that there is an ongoing need to reduce equipment, devices and components such as AC-DC charge controllers, that can fail due to vibrational shock, particularly in weather conditions of −20 C and below where components within devices become more brittle and are at increased risk of damage due to vibration and jarring. Further, if devices and components are minimized the total amount of electrical wiring and wiring terminations are also minimized. This is advantageous in off-grid applications because the fewer wire terminations, the lower probability of equipment failure resulting in expensive call outs for maintenance.

Another drawback of embodiments of Canadian patent 2,851,391 and many other prior art systems is that the ICE is required to run when powering any AC receptacle supplying load to ancillary equipment. In cases where solar or other renewables are used to store electrical charge in a battery bank, the ICE is still used to power AC receptacles and therefore the operator gains no value of renewable power input stored within a battery storage system. As a result of this drawback the inventors have realized that there is a need for the system, its components and any ancillary load connected to the system to have the ability to utilize electrical energy from a renewable resource as a first priority, only using the ICE and consuming fuel as a supplement to renewable electricity stored, or lack thereof, in the battery bank. For example, if solar input into a system is 10 amps at 24V there is more than enough energy to power a small tool or laptop computer. However, since these devices typically require AC power, there is no way for the system to provide renewable power to them. As a result, in prior art systems the value of renewable energy is stored in the battery bank is unavailable to the ancillary load requiring AC power so the operator is compelled to run the ICE and consume unnecessary fuel, even at times where the battery bank may have a full charge.

Further, those with knowledge regarding engines, engine exhaust systems and engine load management are aware that running an ICE a very low, or idle, load for extended periods of time, doesn't permit the correct amount of pressure and/or heat within the engine and/or exhaust circuit to properly vacate combustion gas, particulate and chemicals. This may result in premature engine aging and failure along with all related expenses and operation downtime. To solve this problem, the inventors have identified a need to configure an ICE with a battery storage system in a manner that, when charging a battery system, enables an ICE to remain under a load of more than 50% for the majority of the charging time.

A drawback of all prior art systems using AGM batteries as the primary battery storage system, whether a solar-only light tower or a light tower with an ICE paired to solar panels, is that due to known performance of these batteries they (a) prematurely age when used in outdoor applications particularly if they are charged, either by an ICE or solar, while frozen, (b) they can only be charged at a rate of 10-25% of the total bank rating per hour, (c) require a 3-stage charging algorithm (wherein 2 of the stages require continued ICE runtime at very low energy draw resulting in excessive fuel consumption and premature ICE aging and maintenance), and (d) the system should only use the top 50-60% of the batteries SOC capacity. The inventors have realized that there is a need for a battery system that (a.1) has better capacity to charge and discharge in cold environments, (a.2) has a mechanism to limit battery charging when the batteries are frozen while still permitting electrical draw from the batteries, (b) can charge at a rate of 1:1 or more of the battery bank rating, (c) requires only 1 or 2 step charging algorithm and can be configured to only or primarily charge at a rate high enough to keep the draw on an associated ICE at 50% or more and (d) allows the user to access 70-100% of the batteries SOC without prematurely ageing the battery cells.

Another drawback to prior art systems is the operator is required to manually turn on the ICE and/or lights either by a timer or a switch. In the case of embodiments of Canadian patent 2,851,391 an algorithm can be written and hard coded into a PLC to associate the lighting schedule with sunrise and sunset of a specific geography, however this would generally be time consuming and not economically feasible for all geographies on earth. The inventors have realized that what is needed is a mobile lighting system with built-in circuitry, algorithm and/or coding enabling the system can locate itself anywhere on earth by receiving data from a satellite relating to its global position and other key metrics, associate that information with locale sunrise and sunset times or values then auto-manage the systems lighting schedule to mirror those times.

When the preceding drawbacks to prior art systems are collectively considered, the inventors have realized that there is a need for a mobile lighting system that converts fuel to mechanical energy to DC electrical energy for storage in a battery bank. The system should comprise a sub-system allowing an AC power draw to access energy stored in the battery bank as a first priority to new electrical generation resulting from fuel consumption. The system should comprise a battery bank that can accept power from an ICE that allows the ICE to run in a manufacturer preferred operating range, for example 50-100% load. The system may further comprise a method of self-location, data processing and automatic light schedule management. This new lighting and energy management system should preferable be designed and configured to enable a shorter ICE runtime as a percentage of light time bring provided by the lighting system when considered in relation to a prior art system. Minimizing the ratio of engine runtime to time of light being provided by the lighting system should be a key deign consideration.

### SUMMARY OF THE INVENTION

According to a first aspect, there is disclosed a portable hybrid lighting system comprising: at least one light system operatively supported by a mast; an internal combustion engine (ICE) having a direct current power generator configured to generate direct current directly from mechanical energy; a battery storage system, the battery storage system being operatively connected to the at least one light system and to the ICE and being configured: to store electrical power from the ICE direct current power generator, and to provide stored electrical power to the at least one light system.

The direct current power generator may comprise a dynamo. A dynamo may use electromagnetic induction to convert mechanical rotation directly into direct current through the use of a commutator.

It will be appreciated that in direct current (DC) the flow of electric charge is only in one direction whereas in alternating current (AC), the flow of electric charge periodically reverses direction. DC may encompass currents which are substantially constant and/or currents which vary with time (whilst not reversing direction), such as pulsed DC.

Using a DC generator may allow electrical energy to be provided directly to one or more batteries of at least one battery storage system. This may mitigate the need for AC to DC charge controllers or assisted wiring and may reduce manufacturing and operating costs and increase reliability.

The hybrid lighting system may comprise an AC/DC inverter. An inverter may at least be configured to receive DC input (e.g. from the battery) and output AC. The hybrid lighting system may comprise an AC/DC inverter configured: to simultaneously receive direct current power from the direct current power generator and the battery storage system; and to provide an alternating current power supply from the received direct current power. This may allow AC current power to be drawn from the direct current power generator and/or battery and/or renewable energy system. The AC power may be used to power auxiliary loads (e.g. power tools) via sockets. To ensure the inverter is not consuming power when receptacles are not in use, an inverter power line may be interrupted and configured to a switch, relay or other control device so that the inverter is enabled only when AC receptacle power is required. For example, a typical AC/DC inverted may consume 5-10 amps at 24 volts as heat dissipation when in idle mode, standby or when waiting for use. The power may be consumed by cooling fans, resistors, coils, or other electronics or components dissipating heat. As the present invention is designed to minimize or otherwise reduce wasted power, the AC/DC inverted may only be permitted to consume power when it is supplying power to the AC receptacles or another load/draw configured to it. Similarly, components or other electrical devices configured within the system that would consume energy when the ICE is off should be considered and if possible prevented or limited from drawing power unless the ICE is running or unless their use is called for by the system or ICS. For example, in various embodiments, resistors, coils, bridges, rectifiers, caps, and/or the like required for use of a DC motor or alternator may be controlled with a switch, relay or other means, to disabling them from drawing power until the component they are paired to is required for a functional purpose as required by the ICS or operator. Of course components such as the control system may not be in this category as it is required to keep the system performing as designed. However just like battery heaters or lights only consume energy when their function is called for, so any electric components associated with the DC motor or its ability to effectively provide DC power to a battery bank, or the battery banks' ability to receive power from a DC source or other system components, should only be enabled to draw power when their function is called for.

By powering AC loads (e.g. auxiliary loads via one or more AC power sockets) from the battery (via the AC/DC inverter), the ICE may not need not be run when providing AC power. This may reduce engine run time when compared to prior art systems which must run the ICE in order to power the AC sockets. Furthermore, by powering AC loads via the battery, the maximum power demand on the ICE may inherently be better controlled. For example, in a system where the ICE is configured to drive an AC generator which is configured to provide power to charge the battery (via a AC/DC rectifier or battery charge controllers) and for varying auxiliary AC loads, the ICE and AC generator should be able to provide enough power for all of the loads simultaneously or be configured to actively limit the proportion of power delivered to the battery when an auxiliary AC load is being used. In the present case, the maximum power required may correspond to the power required to charge the battery, because if an auxiliary load is turned on, DC power is automatically diverted from charging the battery to powering the AC load. This permits the use of a reduced size ICE thereby reducing cost and as it typical when utilizing a smaller ICE, increase fuel consumption efficiency. By way of example, for a prior art system to be capable of powering a maximum of 7,500 W of AC plus up to 7,500 W to battery charge controllers, in the prior art systems the operator would be required to either provide an engine/generator rated for 15,000 W-20,000 W or limit available power to either the AC sockets or the battery charge controllers when the other is in use via controlling circuit or manual operation. By contrast, in the example above the present invention could utilize a 7,500 W engine/generator combo for less cost and greater fuel efficiency without having to limit power or function.

The light system may comprise one or more lights. The light system may comprise one or more direct current (DC) lights configured: simultaneously to receive direct current power from the battery storage system and/or the direct current power generator; and generate light directly from the received direct current power. The DC lights may also be configured to receive power simultaneously from one or more other DC sources connected to the lighting system (e.g. DC renewable energy systems). By operating in DC the various available DC power sources may be combined more easily than various AC sources (e.g. because phase is not so important nor is it required to change, each change sacrificing efficiently via heat energy waste). The light system may comprise one or more direct current (DC) lights configured: to receive direct current power directly from one or more DC sources (i.e. without an intermediate AC stage) such as the battery storage system and/or the DC power generator. DC lights, such as LEDs, may mitigate the need for an inverter and/or rectifier between the battery and/or generator and the lights. A light system may be a light emitting diode (LED) light system. Alternatively, the system may be configured with AC powered lights which derive their power via the AC end of the inverter. In this case the system would recognize the AC load for the lighting powered in as if it was an AC load for ancillary power needs at the sockets.

The inverter may be an 8000 W inverter configured to receive 24V DC input and provide 120V AC and/or 240V AC output. In other embodiments larger or smaller inverters may be used or alternatively more than one may be configured to the system.

The portable hybrid lighting system may be configured simultaneously to provide, from the battery storage system and the direct current power generator, direct current power to an external DC load.

The battery storage system may comprise a lithium ion battery configured to store electrical power from the ICE, the direct current generator, a renewable source, gird power, or other ancillary power source.

A lithium ion battery bank or energy storage system may comprise a lithium iron phosphate (LiFePO₄) battery or group of batteries. A lithium ion battery bank may comprise a Lithium cobalt oxide (LiCoO₂) battery. Lithium iron phosphate batteries may offer longer lifetime, better power density (the rate that energy can be drawn from them) and/or better safety.

Lithium ion batteries may have a larger usable bulk charging phase than other batteries. That is, Lithium ion batteries may enable more efficient charging over 90% of the span of its state of charge, whereas an AGM battery may enable efficient charging only for the top 50% of the state of charge. This means that a lithium ion battery or battery bank with a smaller power rating may be used in place of an AGM battery or battery bank. That is, lithium ion batteries including lithium iron batteries provide an operable charging range of 5% SOC to 100% SOC whereas lead acid batteries are substantially more limited in functional range, typically 50% SOC to 90% SOC.

Further, lead acid batteries are generally limited to accepting power at a changing rate of 10-25% of the amperage rating of a given battery bank. Lithium Iron battery bank can be configured to accept a charge at a rate equal to or multiples of (e.g. up to five times) the amperage rating of a particular bank. It is important to note this can substantially reduce ICE runtime due to higher charging input rates and significantly less input limitations for AGM batteries of prior art systems. In prior art systems where AC to DC charge controllers were used to convert an AC load from a generator into lead acid batteries, the ICE would have to run and consume fuel until the batteries were charged to a desired SOC. Due to charging limitations this would result in longer ICE runtimes than in the configuration of the present invention. Synergistically within the present invention when Lithium Iron batteries are used and paired with a DC generator, the battery bank can be charged with substantially reduced ICE runtimes. This reduces ICE maintenance and downtime related to ICE runtime and improves fossil fuel efficiency when consuming for power needs. Furthermore, due to Lithium battery charge capacity and in particular when pairing with a DC motor, the ICE can be sized such that when its running it load or power output is 70-100%. With specific regard to ICE health this permits ideal condition for ICE pressure, exhaust pressure and temperatures and minimized requirements for ICE maintenance and cleaning. That is, matching the ICE to the charge capacity allows the engine to operate towards the top of the performance curve of that ICE.

For example an 800 amp-hours lead acid battery bank being charged by two 40 amp charge controllers (deriving their AC power from an 8 kW AC ICE/generator combination) between an SOC range of 50% and 80% may take 3 hours to charge (=800 ampere hours×30%/(40 ampere×2)), resulting in 3 hours of ICE runtime. A DC generator on the same engine as above can charge an 800 amp-hours lithium iron battery bank between 10% SOC and 80% SOC within approximately 1.5 hours (=800 ampere hours×70%/370 ampere). Therefore the ICE runtime is cut in half while providing around 2.5 times the energy to a battery bank. It is understood to those skilled in the art that the second option may consume a marginal amount of fuel more than the first option during the first 1.5 hours; however this is offset by the reduced total run time so the mass balance effect is overall fuel savings. This may be the case in the example of the 8 kW power source and has an increasing favorable affect as the power source increases, for example a 20 kW ICE/generator combination, due to ICE piston size and efficiency losses of a large ICE runtime when only providing low power relative to its capacity. Furthermore it may be desirable, due to ICE health, operation and maintenance issues, that an ICE is preferably under a load of 60-100% while running. Further, in the example above where an AC generator is used, there are losses of fossil fuel energy in the form of heat energy to the charge controllers as they convert AC to DC. Conversely when a DC generator provides power directly to the battery bank and/or lighting system, there are no such thermal losses which further reduce fuel consumption.

In the past, lithium ion batteries have been expensive, however recently the auto industry and mass production have brought the price within an economic range suitable for a hybrid lighting system. Therefore in some cases there is a need to have an energy management system that functionally permits a battery bank to be maintained within ideal battery operating conditions even when the system operating in non-ideal external weather conditions. In such cases, the use of lithium ion batteries may be preferable as lithium ion batteries may have a larger operating temperature range.

Pairing a DC generator to a battery bank of lithium iron batteries or lead acid batteries provides a means of reduced ICE runtime while allowing the ICE to be under a higher load ratio then would typically be permitted by an AC generator with AC to DC charge controller configuration, whether or not lithium iron batteries are used.

Further as is known, charge/discharge cycles that dictate the useful life of a battery bank are in the thousands for lithium ion battery types whereas they are in the hundreds for lead acid batteries. Additionally, for a mobile lighting system the lithium iron battery bank of a specific design may weigh less than the lead acid counterpart. This may allow more units per truck load to be transported between destinations and/or make the light tower more maneuverable. Additionally, anything that can reduce weight on a machine that is used in remote location often without paving is desirable, especially in raining or muddy conditions.

The battery storage system may comprise one or more batteries. The battery storage system may comprise one or more thermally insulated batteries. The insulation may comprise expanded foam. The battery storage system may comprise a thermally insulating casing (e.g. made of plastic with a thickness of, for example 2.5-3 inches). The casing may comprise iron based (e.g. steel) electrical connectors configured to connect to corresponding copper connectors inside the casing and to corresponding copper connectors outside the casing. Such an arrangement may allow electricity to pass from the battery inside the casing to circuitry outside the casing and reduce thermal or heat transfer between the inside and outside of the casing. This may help maintain the battery temperature within an optimum operating range, particularly in sub-zero conditions.

The hybrid lighting system may comprise at least one renewable energy system operatively configured to generate electrical power from renewable energy. The at least one renewable energy system may be configured to generate power from any one of or a combination of solar power and wind power. The at least one renewable energy system may be configured to generate direct current power directly from the renewable energy.

The hybrid lighting system may comprise a heating system operatively connected to the ICE and/or a control system to heat the ICE when the ICE is off and/or just prior to an operator or the control system requiring ICE runtime.

The hybrid lighting system may comprise a battery heating system operatively connected to the battery storage system to heat the battery storage system to maintain the battery storage system within a temperature range.

The hybrid lighting system may comprise a heat exchanger connected to the ICE to capture and recycle heat released from the ICE, the heat exchanger configured to warm the ICE and/or the battery storage system.

The hybrid lighting system may comprise a grid power connector configured to connect the hybrid lighting system to a power grid in order to receive and deliver grid power to the light system, battery bank and/or an external load. The power grid may comprise an alternating current (AC) power grid or a direct power (DC) power grid.

The hybrid lighting system may comprise a network connection system configured to connect the controller to a remote computer. A GPS may be employed to allow communication between systems and/or between a system and an operator.

The hybrid lighting system may comprise a control system operatively connected to the direct current power generator and the battery storage system. The control system may comprise an integrated circuit board or PCB. To further reduce cost, space and wiring with their connection and termination points, a circuit board may be desirable. The circuit board may have relays and other connections integrated as a means for operational control trouble shooting and efficient updating of a fleet of systems.

Further, a control system comprising programming, sequences and/or codes that convert a GPS locator signal input into a lighting on-off schedule may be included as a means of global distribution of the present invention without the need to program a geographically specific lighting schedule at the manufacture stage. In this example an operator may receive a system in the middle of South America or Africa with the same factory source code. Upon arrival in both cases the operator would initiate an action, for example press a button or enable system in a ready mode that would allow the newly deployed system to determine its location (e.g. latitude, longitude and/or altitude). Once the system control has established is location coordinates it may then search its code for the lighting schedule appropriate for its determined location. The lighting schedule may be derived from code regarding solar activity including sunrise and sunset information for various geographic locations around the globe. The lighting schedule may update daily or at other predetermined intervals.

The battery storage system may be operatively connected to the control system, the control system being configured to: monitor a current state-of-charge (SOC) within the battery storage system; turn on the ICE to generate electrical power when the current SOC is below a lower SOC threshold and/or based on an operator programmed start time; turn off the ICE when battery power is above an upper SOC threshold and/or when an operator programmed runtime has been achieved; direct ICE power to charge the battery system between the lower and upper SOC thresholds and/or operator programmed runtimes; and direct ICE and/or battery power to the lighting system if required; wherein the control system provides a means of energy management and may control charging of the battery storage system in order to reduce ICE fuel consumption by prioritizing charging of the battery storage system between the upper and lower SOC thresholds.

The control system may include a battery charging algorithm and the upper and lower SOC thresholds are the bulk stage of the battery charging algorithm and the battery charging algorithm only charges the battery system within the bulk stage of the battery charging algorithm defined as a bulk charging cycle. The hybrid lighting system may comprise one or more DC-to-DC converters to convert the power generated by the direct current power generator. For example, a DC-to-DC convertor may comprise one or more of: a switched-mode convertor such as a boost converter or step-up converter or buck convertor or step-down convertor, a linear regulator. The DC-to-DC convertor may be configured to convert the DC power input generated by the direct current power generator directly into a DC power output (i.e. without converting to AC). A step down converter may be configured as a means to allow a 12v DC ICE starter battery or battery bank to maintain a full or close to full charge using a 24v DC battery bank as a power source. In one embodiment, the 12v DC battery may be used to power other loads within or outside of the system. The control system may require ICE power when the 24v DC bank SOC drops below a threshold as a result of a load drawing down the 12v DC battery or battery bank when operatively connected to the 24v DC bank via a DC-to-DC step down. When using a step down charger in a preferred embodiment configured to the present invention, it is desirable to configure the step down charger with an isolated ground. For example, a 10 amp 24v DC to 12V DC step charger with an isolated ground.

The control system may include a battery charging algorithm and the upper and lower SOC thresholds are the bulk stage of the battery charging algorithm and the battery charging algorithm only charges the battery system within the bulk stage of the battery charging algorithm defining a bulk charging cycle.

The control system may initiate a maintenance charging cycle after a pre-determined number of bulk charging cycles or a specific maintenance time and wherein the maintenance cycle charges the battery system to 100% SOC.

The control system may monitor the number of bulk charging cycles and the maintenance charging cycle is initiated after a pre-determined number of bulk charging cycles. The pre-determined number may be 10-100 bulk charging cycles. The control system may initiate a maintenance charging cycle after a pre-determined time period.

The control system may enable the battery system to be charged in a range between a lower threshold SOC and 100% SOC or a lower threshold and 90% SOC.

The system may include a renewable energy system operatively connected to the control system which may be any one of or a combination of solar power and wind power.

The at least one light system may comprise a light emitting diode (LED) light system.

The system may include a heating system operatively connected to the ICE and/or control system configured to heat the ICE when the ICE is off.

The system may include a battery heating system operatively connected to the battery storage system configured to heat the battery storage system to maintain the battery storage system within a temperature range. A heating system may be a coolant heater configured to circulate heated coolant to the ICE and/or the battery storage system. A heating system may comprise a DC heater configured to generate heat from a DC current (e.g. DC power provided by a DC battery bank may be used as a means to heat the battery or battery bank supplying the power). In another preferred embodiment aluminum plates may be disposed between the batteries within the battery bank, each aluminum plate configured with a heater, such as a heating rod. The heater to heat the aluminum plate and the aluminum plates to radiate heat into the adjacent batteries. Alternatively, the battery heater may be configured to the AC end of the inverter, although this is a less desirable configuration due to power conversion losses within the inverter.

The battery heating system may be configured to be initiated in response to: the battery temperature being below a predetermined threshold; and/or the battery SOC falling below a predetermined level. The ICE may be configured only to turn on to charge the battery storage system when the battery temperature is higher than a predetermined threshold. In this way, the battery may be configured only to be charged when it is sufficiently warm to enable effective charging without damage to the battery cells or chemistry.

The battery heating system may include a valve between the coolant heater and the battery storage system configured to control the flow of heated coolant between the coolant heater and the battery storage system. The valve may be temperature-controlled.

A fuel heater may be configured to the fuel filter, fuel tank and/or fuel lines in a manner to help prevent, reduce or minimize gelling of fuel in extremely cold weather. The fuel heater may be a fuel filter heater powered by a DC current from with the 12V or 24V source. Alternatively, the heater may be configured to the AC end of the inverter, although this may be less desirable configuration due to power conversion losses within the inverter.

The control system may include means for monitoring the temperature of the ICE, the fuel system, and/or the battery system and turning on and off the various heating systems when one or more threshold temperatures are reached and/or based on timer controlled schedule.

The system may include a mast supporting a wind turbine having a telescoping shaft retractable within the mast. In some embodiments, the wind turbine includes: a rotor having at least one blade, the rotor rotatably and swivelably connected to the telescoping shaft; a rod attached to the rotor; and an angled plate attached to the mast and having a slot configured to receive the rod and preventing the rotor from swiveling when the telescoping shaft is retracted, wherein the angled plate is designed to direct the rod into the slot by causing the rod and rotor to swivel. The angled plate may include at least one bumper extension oriented to contact the at least one blade as the telescoping shaft is retracted to prevent the at least one blade and rotor from rotating.

A rotor may comprise one, two or more than two blades. The angled plate may comprise at least one bumper extension for contact with one of the least two blades when the wind turbine is retracted.

The system may include a base for supporting at least one array of solar panels. The solar panels may be pivotable about a horizontal axis on the base. The system may comprise two arrays of solar panels on opposite sides of the base. The base may comprise at least one angled wall and the at least one array of solar panels is pivotably connected to the angled wall.

The system may include a light sensor (e.g. a photocell) configured to sense ambient light levels and turning the at least one light off or on based on the ambient light level. The light sensor may be connected to the at least one light. The system may include a heat exchanger connected to the ICE for capturing and recycling heat released from the ICE for warming the ICE and/or battery storage system. The system may include an auxiliary load connection for connecting to and providing power to an auxiliary load. The system may include a grid power connector for connecting the hybrid lighting system to a power grid for receiving and delivering grid power to the light system, battery bank, inverter, control system and/or an auxiliary load. The system may include a network connection system for connecting the controller to a remote computer. The grid power connector may enable connection of the hybrid lighting system to a power grid (e.g. a local DC power grid or national power grid) for providing power to the grid generated by the hybrid lighting system (e.g. via the ICE and DC generator and/or one or more renewable energy systems).

The system may include a user interface operatively connected to a control system to allow a user to control functionality of the device. The user interface may comprise a mast switch or button for raising and lowering the mast.

The system may be configured such that, when the mast is in a lower position, for example fully retracted for transport or storage, any one or all of the ICE, lights, inverter, solar or any component(s) of the control system is deactivated. In various embodiments the act of placing the system in storage or transport position ensures minimization of power consumption and ultimately reduces fuel consumption.

The system may be configured with a switch that would allow an operator to selectively deactivate the inverter when receptacle use is not required. In an alternative embodiment the receptacle cover may be configured with a limit switch that permits activation of the inverter only when the receptacle cover is lifted, indicating to the system that AC load requirements and therefore use of the inverter is needed. In another embodiment the inverter may be controlled by a timer so that receptacle power is provided at specific intervals within a longer timeframe.

The user interface may include an engine activation switch operatively connected to the control system, the engine activation switch configured to control activation (e.g. turning on and off) of the engine. The engine activation switch may have an auto-run position for activating the control system to activate the ICE based on pre-determined operational parameters.

In another preferred embodiment there may be no ICE activation switch for normal daily system use. In this embodiment the ICE is controlled by the control system to only turn on when the battery bank is at or below a specified lower SOC threshold. In this way, all power consumption needs, whether direct from the battery or its associated power sources or through an inverter, are drawn from the battery bank first, and it's only the battery bank SOC that can signal for ICE on. Of course for maintenance an override switch configurable to the ICE may be used.

The system may include at least one panel of solar panels. The system may comprise a user interface operatively connected to the control system, the user interface having one or more of: a mast switch for raising and lowering the mast; at least one solar panel switch for raising and lowering each of the one or more solar panels; and an ICE activation switch operatively connected to the control system, the ICE activation switch having an auto-run position for activating the control system to activate the ICE based on pre-determined operational parameters and an ICE manual-run position allowing an operator to manually run the ICE as needed; and a light activation switch operatively connected to the control system, the light activation switch having a position for activating the lights based on pre-determined operational parameters.

The system may include at least one panel of solar panels wherein the system further includes a user interface operatively connected to the control system, the user interface having one or more of: a mast switch for raising and lowering the mast; at least one solar panel switch for raising and lowering each of the one or more solar panels; and an activation switch operatively connected to the control system, the activation switch having an auto-run position for activating the control system to activate the ICE based on pre-determined operational parameters and/or activate the lights based on pre-determined operational parameters and having manual-run position that starts the ICE which remains on while activating the lights based on the same pre-determined operational parameters as in the auto-run position.

The system may include a user interface operatively connected to the control system, the user interface having one or more of:
a. at least one mast switch for raising and lowering the mast;
b. at least one solar panel positioning switch wherein the solar panels are moved into their deployed position by activating a switch;
c. at least one solar panel wherein by raising the mast the solar panels are moved into their deployed position;
d. an activation switch operatively connected to the control system, the activation switch allowing the system to auto-manage itself without further manual operation from an operator wherein the system is permitted to auto-manage and to activate and deactivate one or more of the following based on pre-determined operational parameters:
   i. the ICE
   ii. the lights
   iii. a battery heating system
   iv. an ICE heating system
   v. an inverter
   vi. permit use of receptacles via inverter;
e. an activation switch operatively connected to the control system, wherein the activation switch enables the system to
   i. auto-manage the ICE based on pre-determined operational parameters
   ii. deactivate the lights
   iii. permit use of receptacles via inverter;
f. an activation switch operatively connected to the control system, wherein the activation switch enables the system to
   i. auto-mange the ICE based on pre-determined operational parameters
   ii. activate the lights for a specified time period, the time period being determined by the operator or by pre-determined operational parameters
   iii. permit use of receptacles via inverter.

The system may comprise a controller configured to control the energy input and output of the hybrid light tower having at least one light, an internal combustion engine (ICE), at least one renewable energy system, at least one controller, and at least one battery storage system. The controller may be configured to perform at least one of: monitoring available power from the at least one renewable energy system and at least one battery storage system; switching on ICE power when available renewable energy power and/or battery power is low; charging the battery storage system when the ICE is on; and charging the battery storage system when renewable power is available.

The system may comprise one or more temperature monitors configured to monitor the temperature of the ICE and/or the at least one battery storage system. A controller may be configured to control (e.g. turn on and off, or change the temperature) of a heating and/or cooling system when temperature thresholds are detected by the one or more temperature monitors.

The system may comprise one or more current state-of-charge monitors configured to monitor a current state-of-charge (SOC) within the battery storage system. A controller may be configured to control the ICE (e.g. by turning on or off the ICE or changing operational parameters such as increasing fuel and/or air supply and/or ICE RPM) to control generation of electrical power. For example, the controller may be configured to turn on the ICE when the current SOC is below a lower SOC threshold. The controller may be configured to turn off the ICE when battery power is above an upper SOC threshold and/or when a programmed runtime has been achieved. The controller may be configured to direct ICE power to charge the battery system between the lower and upper SOC thresholds. The controller may be configured to direct ICE and/or battery power to the light system. The controller may control charging of the battery storage system in order to reduce (or minimize) ICE fuel consumption by prioritizing charging of the battery storage system between the upper and lower SOC thresholds.

The controller may comprise programmable timers configured to enable an operator to program one or more times of operation of the ICE for providing power to the at least one light system. The one or more program times may include one or more of the following times: a time when the ICE is on; a time when the lights are on; a time when the ICE is off; a time when the lights are off; a time when a portion of the lights are on and a portion of the lights are off; and a time when the lights are dimmed (e.g. at dusk, dawn, twilight or in the event of an mechanical engine failure).

The controller may control dimming of the lights based on available voltage for the lights (e.g. from the batteries and/or DC generator). For example, if the battery voltage is less than a threshold voltage (e.g. 25 volts) the circuit will reduce the current by 10-20% to extend the battery life (e.g. by 10 hours or more). Controlling the dimming of the lights may be performed as follows:
Step 1: allow battery to discharge to lower threshold (e.g. 50% SOC); and
Step 2: if an engine failure occurs and/or the batteries cannot be charged, then the controller may be configured to step down the voltage to the lights, for example reducing brightness every 30-60 minutes by 10-20%. These figures are exemplary and not meant to be limiting as various embodiments and operator requirements may require different parameters.

The dimming circuit may be associated with a driver board in the light arrays and light tower controller. The dimming circuit may be integrated within the LED Driver.

The system may further include an ICE heating system operatively connected to the ICE for heating the ICE to maintain the ICE within a temperature range prior to start-up that may be a coolant heater or space heater.

The controller may be configured to sense when the ICE has a mechanical failure in which case after being sent a signal to start, the ICE does not start. If this occurs while the lights are on, the light may continue drawing from the battery bank. In order to extend time for which light is provided with limited SOC left in the battery bank, the controller may be configured with a dimming circuit and/or control logic to reduced power provided to the lighting system. For example, if available battery drops below a 50% SOC and the ICE fails to activate on and charge the battery bank, the controller may begin reducing power in a stepwise manner over time. So rather than the lighting system draining the battery bank completely within for example 5 hours, the lights may remain on for 10 hours or more. In this examples the lights may dim by 10-20% every 30-60 minutes. This extended time of battery powered light permits additional time for the operators to identify and fix the ICE problem without loss of light to the operation. In prior art ICE powered systems, the ICE much be on and active to provide light. A draw back to these systems is immediate loss of light with ICE failure.

The hybrid lighting system may comprise a control system configured to:
a. determine the global location; and
b. generate a lighting on-off schedule based on the determined global location.

The hybrid lighting system may comprise a cell monitoring system configured to:
monitor the state of charge in an individual battery cell of a battery storage system;
open a contactor to prevent charging current passing to the individual cell based on one or more of the following:
   if the cell voltage exceeds a predetermined high voltage cutoff; and
   if the cell voltage goes below a predetermined low voltage cutoff.

A contactor may be arranged in parallel with a diode configured to allow discharging current to flow from an individual cell or the battery bank whilst preventing charging current passing to the individual cell.

The hybrid lighting system may comprise a controller having a GPS module and is configured to:
receive a data string from the GPS;
parse the data string provided by the GPS to determine one or more of: the latitude, longitude, altitude, UTC time and date;
calculate sunrise and sunset times based on the parsed GPS data string;
control operation of the lighting system and/or the ICE based on the calculated sunrise and sunset times.

The hybrid lighting system may comprise a dimming controller, the diming controller configured to reduce the voltage to at least one light if at least one battery is below a threshold voltage and/or the ICE has failed to start.

The hybrid lighting system may comprise comprises a signaling module configured to send signals to a user in response to a predetermined condition being satisfied.

The signal may comprise one or more of: a text message, an email, and an audio message.

The predetermined condition may comprise one or more of the following:
the ICE failing to start in response to one or more start commands;
the total runtime of the ICE exceeding a predetermined threshold;
the system running low on fuel;
any battery cell or the battery bank going beyond a predetermined working range.

According to a further aspect, there is provided an energy management system comprising: at least one light system operatively supported by a mast; an internal combustion engine (ICE) having a direct current power generator configured to generate direct current directly from mechanical energy; and a battery storage system, the battery storage system being operatively connected to the at least one light system and to the ICE and being configured: to store electrical power from the ICE direct current power generator, and to provide stored electrical power to the at least one light system.

### BRIEF DESCRIPTION OF THE DRAWINGS

The invention is described with reference to the accompanying figures in which:

FIG. 1 is an end view of a skid-mounted hybrid light tower showing a light mast in a collapsed position and one solar panel in a deployed position in accordance with one embodiment of the invention.

FIGS. 2 and 3 are side and front perspective views of a skid-mounted hybrid light tower showing a light mast in a collapsed position and one solar panel in a deployed position in accordance with one embodiment of the invention.

FIG. 4 is an end view of a skid-mounted hybrid light tower showing the light mast in an erected position and a deployed solar panel.

FIG. 4A is an end view of a trailer-mounted hybrid light tower with a windmill showing the light mast in an erected position and a deployed solar panel.

FIG. 4B is a perspective view of a trailer-mounted hybrid light tower showing the light mast in an erected position and a deployed solar panel in accordance with a wind-powered embodiment of the invention.

FIG. 5 is a perspective view of a skid-mounted hybrid light tower showing the light mast in an extended position in accordance with one embodiment of the invention.

FIG. 5A is an end view of a trailer-mounted hybrid light tower showing the light mast in a retracted position in accordance with a wind-powered embodiment of the invention.

FIG. 5B is a perspective view of a trailer-mounted hybrid light tower showing the light mast in a retracted position in accordance with a wind-powered embodiment of the invention.

FIG. 6 is an end view of a trailer-mounted hybrid light tower showing each solar panel in a maximum deployed position.

FIGS. 7A, 7B and 7C are schematic views of a trailer-mounted hybrid light tower showing solar panels in a retracted position (7A), low sun angle deployment (7B) and high sun angle deployment (7C).

FIG. 8 are side and front views of a light mast in an extended position with a wind turbine.

FIG. 9 are rear perspective views of a retracted light mast with a wind turbine.

FIG. 10 is a rear perspective view of a hybrid light tower mast in a retracted position with a wind turbine.

FIG. 11 is a rear view of a hybrid light tower mast in a retracted position with a wind turbine.

FIG. 12 is a schematic diagram of the various sub-systems of a hybrid light tower having an intelligent control system (ICS) in accordance with one embodiment of the invention.

FIG. 13 is a schematic diagram of various optional sensor inputs to an intelligent control system (ICS).

FIG. 14 is a schematic diagram of a heating system in accordance with one embodiment of the invention.

FIG. 15a is a graph showing state-of-charge vs. time of a battery bank in accordance with a system described in the applicant's previous application, PCT/CA2013/000865.

FIG. 15b is a graph showing state-of-charge vs. time of a battery bank in accordance with an embodiment of the invention according to the present disclosure.

FIG. 16 is a schematic diagram of a control panel in accordance with one embodiment of the invention.

FIGS. 17a-17e are a series of views of a further embodiment of a skid-mounted hybrid light tower.

FIGS. 17f-17h are views of the control panel box of the embodiment of FIG. 17a.

FIGS. 18a-18b are a series of views of a further embodiment of a trailer-mounted hybrid light tower.

FIG. 19a is a perspective view of a heat diffusion plate with heater rod/wiring.

FIGS. 19b-c are perspective views of an insulated battery bank box having an ICE starter battery and a series of storage batteries.

### DETAILED DESCRIPTION OF THE INVENTION

With reference to the figures a portable (e.g. skid-mounted, wheeled and/or collapsible) hybrid-power-source lighting and energy management system (referred to herein as a hybrid lighting system or HLS) 10 is described. The system utilizes a battery storage bank and an internal combustion engine (ICE) with a direct current power generator to power a light system and other internal and/or ancillary loads. The HLS may have an intelligent control system (ICS) comprising at least one controller that efficiently manages energy consumption and delivery. The overall philosophy of design is to reduce (e.g. minimize) engine runtime which in turn reduces (e.g. minimizes) fuel consumption.

In various embodiments the system utilizes solar and/or wind energy in conjunction with ICE energy. Generally, for those embodiments utilizing renewable energy systems, the system may operate to prioritize the use of renewable energy (e.g. wind and/or solar energy) when available but can draw on ICE generated power and/or stored battery power when neither wind nor solar are available in sufficient amounts to power the lighting system and/or auxiliary energy draw. In a condition where renewable components are either not added to the lighting system or if the system is deployed in an environment there the renewable components do not receive power inputs (e.g. from solar and/or wind), the lighting system is still able to reduce ICE runtime, fuel consumption and operator involvement due to the ICS functions and/or other system components such as batteries, LED lighting and/or intelligent battery charging or energy management algorithms. It will be appreciated that the controller may operate to manage the various power inputs in a manner that increases the efficiency for each time segment the ICE is used (or for a particular use cycle). That is, the system is generally designed and operated in order to reduce both fuel consumption and ICE runtime, whether considered separately or together. The system may operate with a user interface that reduces the requirements for user monitoring and/or user contact with the system (e.g. by allowing the user to program future events and/or to define operational parameters for event management).

### Overview

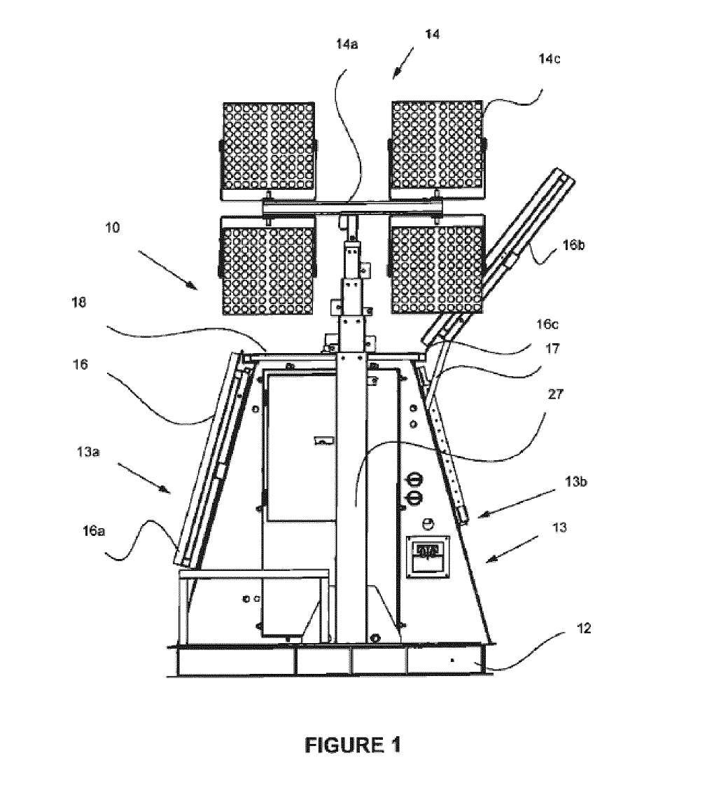

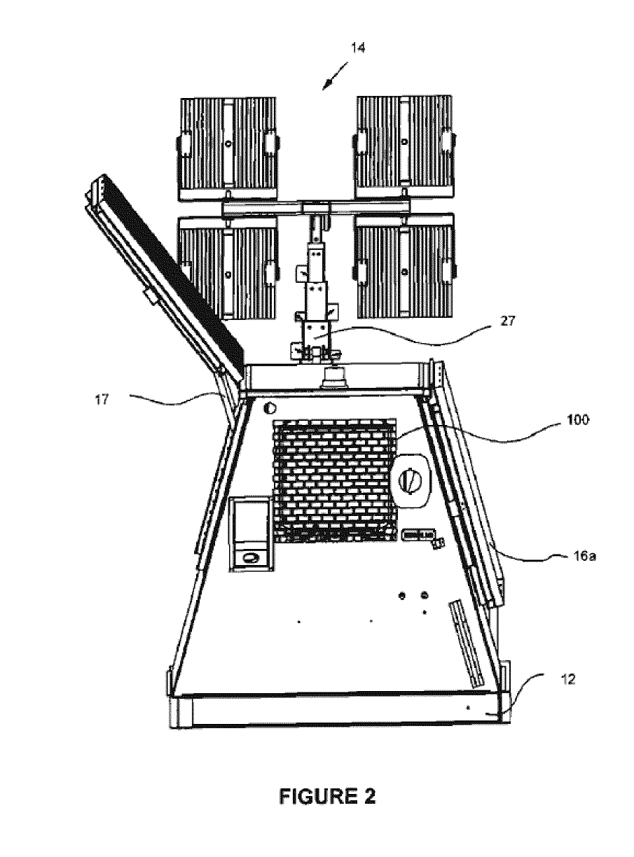

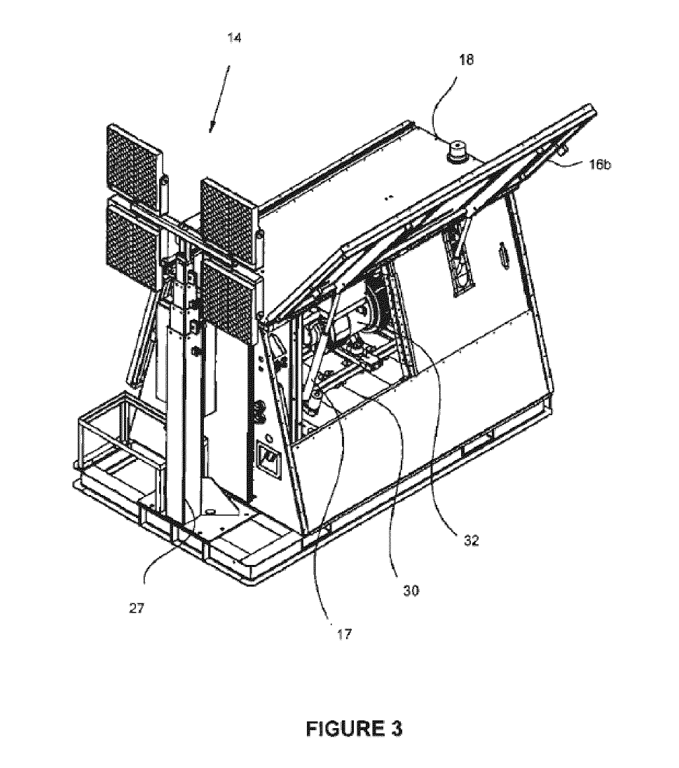

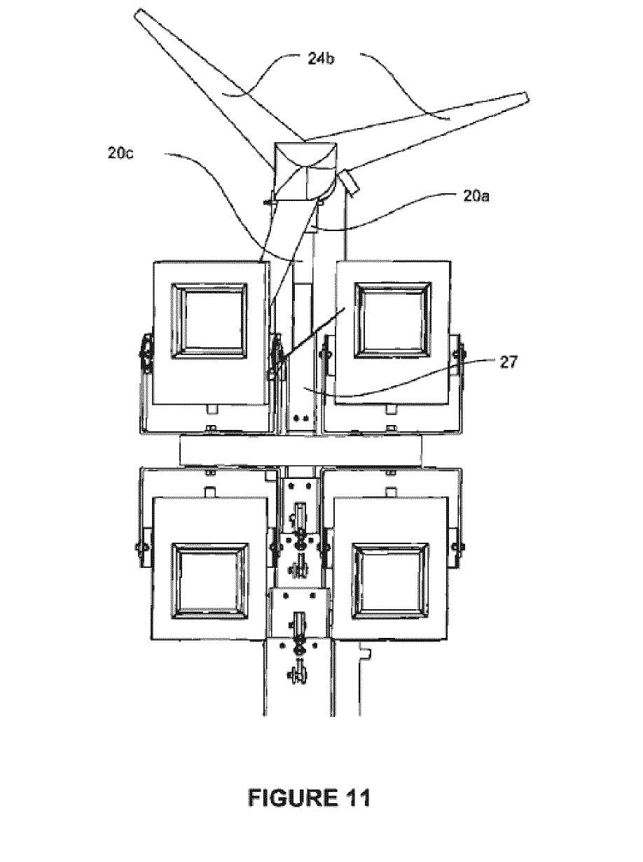

With reference to FIGS. 1-11 and 17-19, various embodiments of the hybrid lighting system 10 are described. FIGS. 11-16 show various control schemes showing different embodiments that can be implemented in the operation of the system. The various physical embodiments include a skid-mounted system, a trailer mounted system, as well as systems having an optional solar panel and/or wind turbine. For the purposes of this description, the system is described as including a solar panel system although it is understood that a system may be designed that does not utilize a renewable energy system. That is, a hybrid system may be considered to be a system which uses multiple energy sources (e.g. from the DC generator and battery). The multiple energy sources of the hybrid system may include renewable energy sources and/or energy from the grid. The hybrid system may comprise multiple energy generators configured to generate energy via different mechanisms (e.g. a generator to generate electrical power from an ICE; a solar cell and a wind-turbine). As such, the system 10 generally includes: at least one light system 14 operatively supported by a mast 27; an internal combustion engine (ICE) 32 having a direct current power generator configured to generate direct current directly from mechanical energy; a battery storage system, the battery storage system 30 being operatively connected to the at least one light system and to the ICE and being configured: to store electrical power from the ICE direct current power generator, and to provide stored electrical power to the at least one light system.

Using direct current (DC) electrical transmission may be more efficient than using alternating current (AC) transmission within the configuration of the present invention. This may be particularly relevant for embodiments where the renewable power source is configured to produce DC current power (e.g. solar panels, or a wind turbine with a DC power generator) and the load is configured to use DC current power (e.g.: LED lights, inverter for AC sockets, system components, etc.). When AC power is not required for ancillary equipment, DC current may be the only current produced, generated and consumed by the system and its devices. Therefore, the present invention in one aspect may be considered a DC only lighting and energy management system.

DC system may be more reliable and can enhance system stability compared with a system, for example a prior art system, in which the ICE generates AC power that must be converted to DC for use by sub-components including the ICE starter battery, a control device, lighting, relays, etc. For example, the operator may not need to take into account phase differences, reactive power and/or frequency variation to maintain stability of the system (as they would for an AC generation system of prior art). This may allow a DC hybrid lighting system to form part of a local DC grid (e.g. comprising multiple interconnected hybrid light towers). It will be appreciated that such a grid may allow more complex combinations of ICEs and battery storage systems to be used to power the light systems than would be possible with each system operating independently. These combinations may be configured to increase the overall efficiency. For example, a grid may comprise a first hybrid lighting system having a solar panel and an interconnected second hybrid lighting system having a wind turbine. It will be appreciated that at night, if there is a wind blowing, the wind turbine of the second hybrid lighting system may be configured to charge the battery storage systems of both the first and second lighting systems and/or provide power to the light systems of both the first and second hybrid lighting systems.

A further advantage of DC power lines is efficiency. For example, less energy may be lost as DC is transmitted (compared with AC) because there is no need for reactive compensation along the line and/or because direct current flows through the entire conductor rather than at the surface (as with AC). Reactive compensation is generally required in AC to take into account the changing direction of the current. Therefore, it may be advantageous for the DC power to be transmitted directly as direct current between the various DC components (e.g. the DC generator, the battery storage system, the light system, a heating system) of the hybrid lighting system. A further advantage is that during manufacturing there is no need for isolated sets of electrical wiring, junctions and terminations. Furthermore, technician's supporting a DC system would require less training and troubleshooting may be minimized.

In this case, the system also comprises a trailer base or skid base 12 supporting a body 13, to allow the lighting system to be moved. The base 12 may be a mobile trailer base that allows the system to be moved to a desired location behind a vehicle or be a skid type base common in the oil and gas industry that allows the system to be moved with an industrial loader or fork lift onto and off a flat-bed truck.

The lighting system may also be configured to derive or capture renewable energy via a renewable energy system, which in this case, is a solar power system 16. The system may also comprise a heating system 26, which may be comprised of one or more individual heating systems. Heating system 26 may comprise one or more of: an ICE heating system, a battery bank heating, a fuel heating system (not shown). In this case, the system also comprises an intelligent control system (ICS) 28, where the ICS may comprise one or more sensing and/or controlling devices working together to manage system energy.

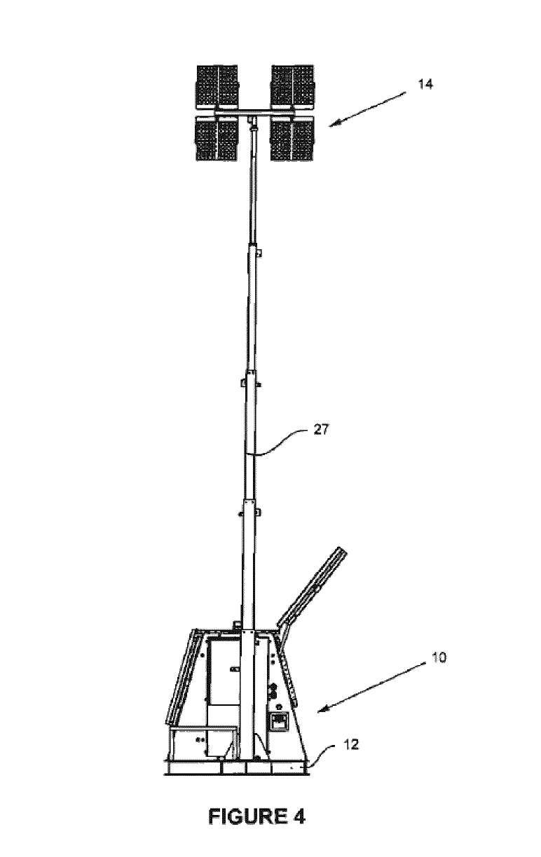

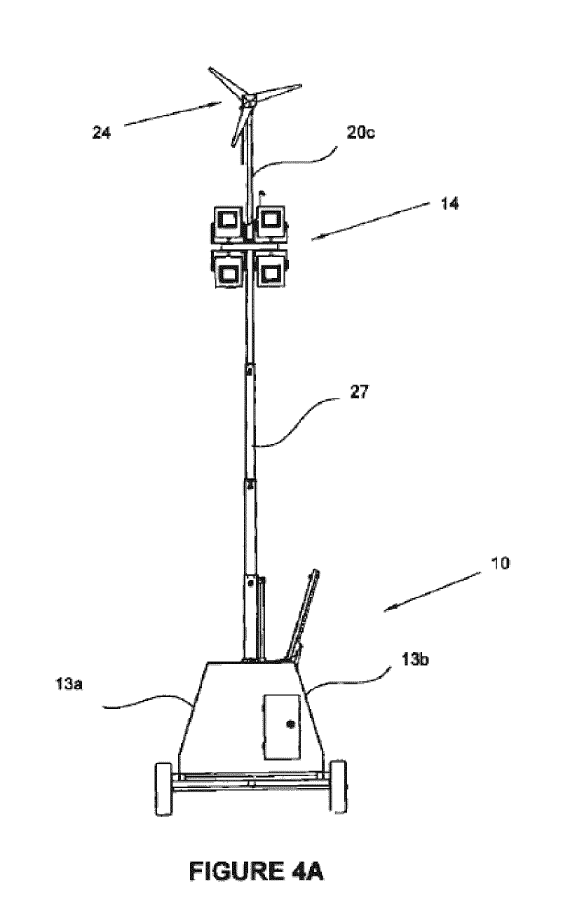

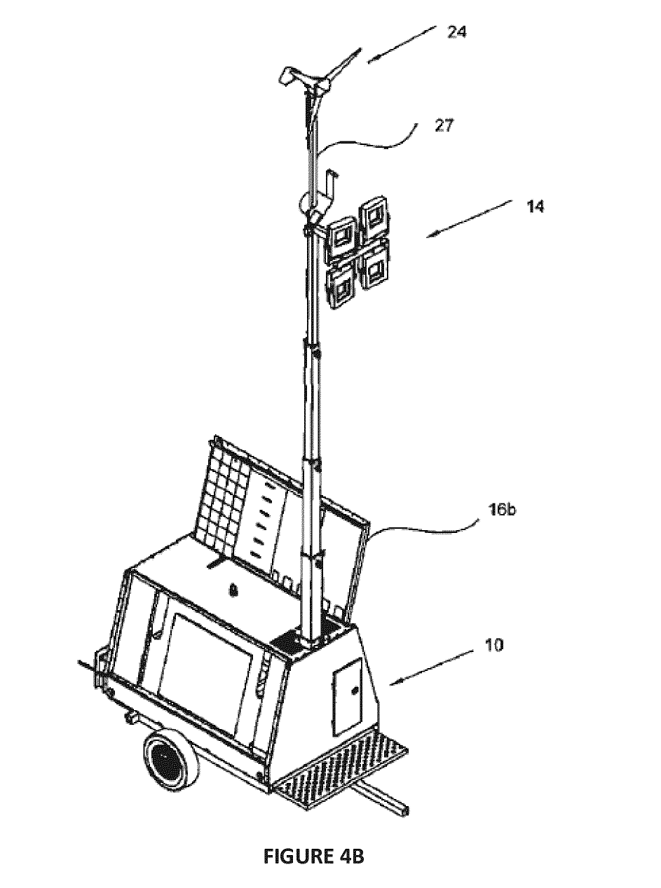

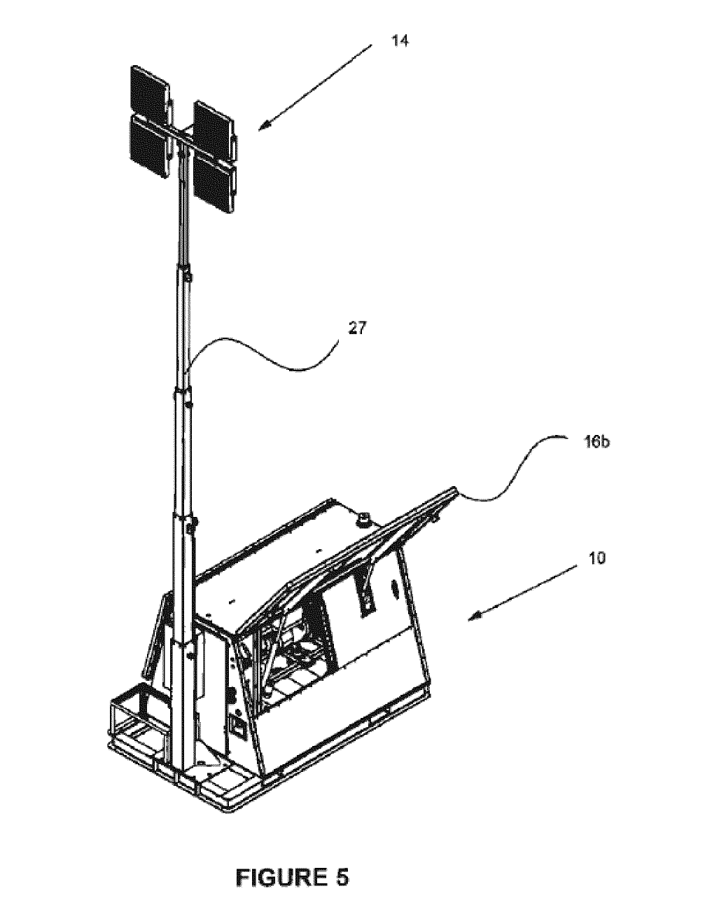

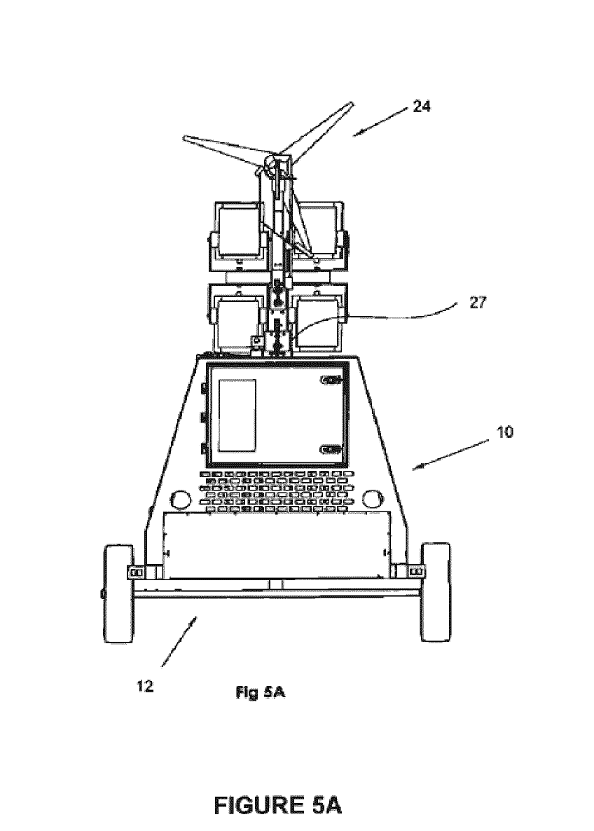

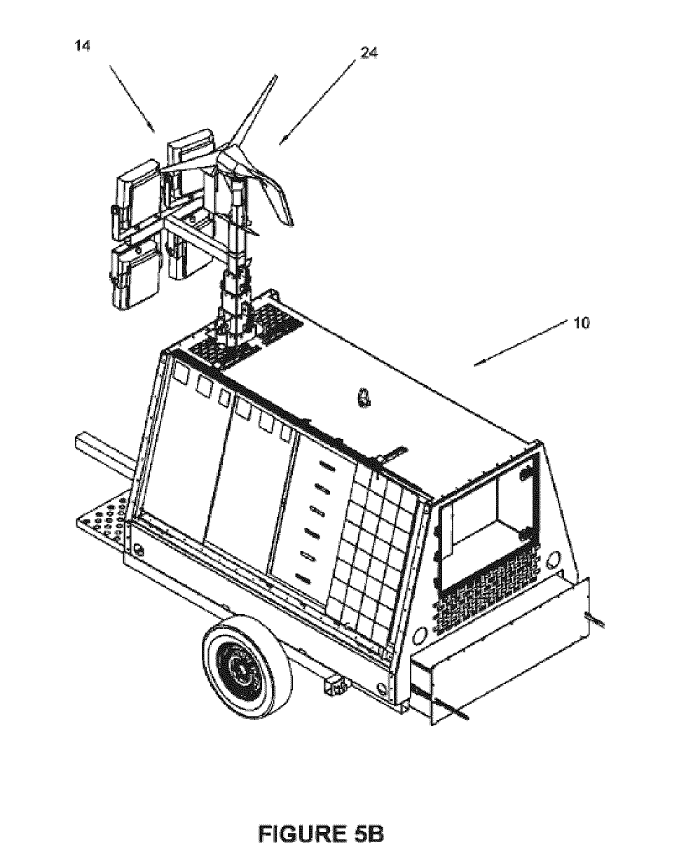

The light tower, in this case, is moveable between a collapsed position (see FIGS. 1-3 for example) for storage and transportation and an erected position (FIGS. 4, 4A, 4B and 5 for example), when the system is in use.

The design and operation of the light tower and associated systems are described in greater detail below.

### Power for AC Loads

The hybrid lighting system may comprise an AC/DC inverter. The AC/DC inverter may be configured: to simultaneously receive direct current power from the connectors of a direct current power generator and/or the battery storage system 30; and to provide an alternating current power supply from the received direct current power source. This may allow AC to be drawn from the generator and/or battery. In some configurations, this may allow multiple power sources to simultaneously provide power to an AC supply (e.g. if the renewable energy source were also connected to the connectors of the direct current power generator). The multiple power sources may comprise a combination of one or more of: a renewable DC energy source; the battery storage system; and the direct current power generator.

By powering AC loads (e.g. auxiliary loads via one or more AC power sockets) from the battery (via the AC/DC inverter), the ICE need not be run in order to provide AC power. This may reduce engine run time. Furthermore, by powering AC loads via the battery (and/or renewable energy sources), the maximum power demand on the ICE may be better controlled. For example, in a system where the ICE is configured to drive an AC generator which is configured: to provide power to charge the battery (via a AC/DC rectifier); and to provide power for auxiliary AC loads, the ICE and AC generator should be sized to provide enough power for all of the loads simultaneously or be configured to actively limit the proportion of power delivered to the battery when an auxiliary AC load is being used. In the present case, the maximum power required may correspond to the power required to charge the battery, because if an auxiliary load is turned on, DC power is automatically diverted from charging the battery to powering the AC load.

The hybrid lighting and energy management system may be configured to transmit power between the various components as DC.

### Mast 27

In this case, the mast 27 is attached to the base 12 for supporting the light system 14 and an optional wind turbine 20. In some embodiments, there may be more than one mast for separately supporting the lighting system and wind turbine, however for the purposes of this example, the lights 14 and wind turbine 20 (where included) are supported on a single mast.

The mast, in this case, can be moved between an extended and retracted position (e.g. via telescoping means) for transportation purposes and/or to adjust the height of the mast. It will be appreciated that in other embodiments, the mast may also pivot between a vertical and horizontal position for ease of transport and storage for some configurations. The mast may be erected using a series of cables and an appropriate motor system to progressively extend sections of the mast.

In some embodiments, connected to the mast is a proximity switch, limit switch or other such switch or sensing device also connected to the system such that certain components of the ICS become deactivated while the mast is in its retracted position, such as the mast position during transport. The automatic deactivation of a PLC, PCB and/or ICE autostart function from occurring, in response to the mast retraction, prevents the system from self-starting while in transport and/or storage without the need for the operator to perform the additional step of system deactivation. This therefore limits human error from contributing to system mismanagement or harm.

In other embodiments the lighting system may have an in-use configuration (e.g. where the ICE provides power to the generator which in turn provides energy to the battery and/or light systems), and a transport configuration (e.g. where the ICE is turned off, or where the ICE is enabled to provide locomotive power to move the lighting system). It will be appreciated that a control system may be configured to change the lighting system between the in-use configuration and the transport configuration based on user input and/or detecting whether or not the mast is in its retracted position.

Some embodiments may be configured such that the AC/DC inverter is activated and made available for use when the mast is raised (or otherwise placed in an in-use configuration). In other embodiments and configurations the inverter can be activated or deactivated by a switch. The switch may be a limit switch configured to the receptacles or a simple on/off switch controlled by an operator. This may be advantageous so that in its resting state the inverter doesn't draw unnecessary power from the battery bank. This ensures fuel is not consumed without a direct operational purpose. When an operator wishes to use the receptacles a switch then activates the inverter.

In other embodiments, the mast position is configured to move between two (or more) proxy switches configured to allow power to the system or place it in sleep, storage or transportation mode. In this case the mast raise and lower switch is connected directly to a battery. The rest of the system is connected to battery or other power though a relay. This way the mast can be raised when the system is not powered. In this way, by raising the mast the system is provided power:

To take the system out of “sleep” or transport mode, in this case, the mast must be raised. Once the mast clears proximity switch 1, the system will activate and automatically default to “auto” mode. Proximity switch 1 will also put the PCB in “sleep” mode when the mast is then lowered to its retracted, storage, transport position.

Proximity switch 2 is in place to detect the mast height extension. Once the proximity no longer detects a ferrous material, or otherwise detects that the mast is up, the PCB will deactivate the mast up button.

Both proximity switches have been configured to be fail-safe.

Sleep mode, in this case, removes power from the inverter, PCB, LCD, light and engine. The clock in the PCB may be maintained by internal battery.

### Light System 14

Referring to FIG. 1, the light system 14, in this case, includes a light attachment member 14a connected to the mast 27, and one or more lights 14c (e.g. light panels) mounted to the light attachment member 14a. The angle and orientation of the lights may be automatically and/or manually adjustable. To adjust the angle, the lights may pivot about the light attachment member. The light attachment member may also pivot or swivel around the mast to effect the orientation of the lights.

It will be appreciated that the light system may comprise one or more DC lights configured: simultaneously to receive direct current power from the battery storage system and/or the direct current power generator; and generate light directly from the received direct current power. The lights may comprise LEDs (e.g. LED panel lights) which may be configured to use DC power. By using DC power, it will be appreciated that the need for an inverter and/or rectifier between the direct current power generator and/or battery storage system may be mitigated. In cases where the DC lights are configured to use a different voltage to that provided by the direct current power generator and/or battery storage system, it will be appreciated that the DC lights may be configured on a lighting circuit such that the voltage supplied to each DC light is provided with the appropriate voltage. For example, the DC lights may be configured in a combination of series and parallel circuits.

Other methods of controlling the voltage may also be used. For example, the hybrid lighting system may comprise one or more DC-to-DC converters to convert the DC power (e.g. power generated: by the direct current power generator; by the battery storage system; and/or by a renewable energy system). A DC-to-DC convertor may comprise one or more of: a switched-mode convertor such as a boost converter, a step-up converter, a buck convertor or a step-down convertor; and a linear regulator. It will be appreciated that using a switched-mode convertor may be more efficient than using a linear convertor. A DC-to-DC converter may be an inverting or non-inverting converter depending on polarity of the output relative to the polarity of the input. A DC-to-DC convertor may be configured to convert a DC power input directly into a DC power output (i.e. without converting to AC in an intermediate stage). It will be appreciated that the DC power output of a DC-to-DC convertor may have different properties than the DC power input (e.g. one or more of: different current; different voltage; and different polarity).

It will be appreciated that some embodiments may be configured to convert a DC power input indirectly into a DC power output via an alternating current stage.

The hybrid lighting system may comprise a DC smoothing circuit configured to smooth pulsed or varying DC current to smooth DC (i.e. direct current with a substantially constant current and/or voltage). The DC smoothing circuit may be configured to smooth direct current produced by a DC power generator. A DC smoothing circuit may comprise a reservoir capacitor configured to store charge when the direct current is higher and releases the stored charge when the direct current is lower.

In some embodiments, the intensity of the lights can be adjusted automatically and/or manually. This may be achieved by one or more of: adjusting the intensity of some of the lights; adjusting the intensity of all of the lights; and turning on or off some of the lights. The lights will typically operate with 12-96 volts; however it may be advantageous to use a light voltage of 24-48 volts to reduce line losses.

A control system may configured to control the power delivered to the lighting system based on the state of charge and/or voltage of the battery in response to determining that the ICE is not available (e.g. if the ICE has been manually disabled, if a fault in the ICE is detected and/or if the conditions, such as temperature conditions and/or timing conditions, for starting the ICE have not been met). For example, if the ICE has been manually disabled but light is required, the power supplied to the lights may be controlled by reducing the current supplied to the lights based on a measured voltage supplied by the battery. In this way, light may be provided for a longer time than if the initial current were maintained until the battery voltage was no longer sufficient to power the lights. By controlling the lights in this way, the duration of lighting may be extended. This would allow a smaller battery bank to be used without sacrificing the duration of lighting available when only the battery is available (e.g. in the event of an ICE failure). LEDs are particularly suited for this application as they may be configured to be dimmable and have low power consumption.

The power rating of the total system lights may range from a few hundred watts to several thousand, depending on the need or the offset lighting comparison. By way of comparison, if a typical standard light tower system consumes 4,000 watts, an equivalent LED lighting system may have a 700-1500 watt rating.

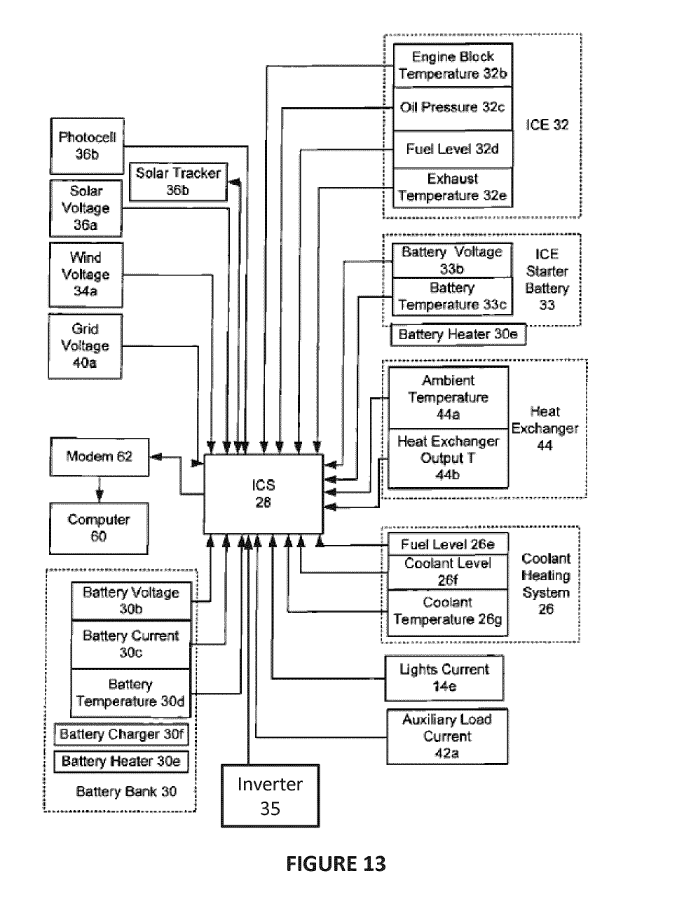

The lighting system may also include a light sensor (e.g. a photoresistor/photocell 36b as shown in FIG. 13) that can be utilized to sense ambient light levels and automatically power all or some of lights on or off at pre-determined threshold points. Similarly, the lighting system may be configured to adjust (e.g. decrease or increase) the light intensity based on the sensed ambient light level.

### Renewable Energy System

The hybrid lighting system may comprise a renewable energy system operatively configured to generate electrical power from renewable energy. For example, the at least one renewable energy system is configured to generate power from any one of or a combination of solar power and wind power.

The at least one renewable energy system is configured to generate direct current power directly from the renewable energy. It will be appreciated that many renewable energy systems are particularly suited to generating DC current. For example, solar photovoltaic (PV) panels produce DC power.

### Solar Panels

In the preferred embodiment the solar panel system 16 includes one or more arrays of solar panels 16a, 16b configured to the body 13 with appropriate mounting systems, hinges, lifting mechanisms and/or scaffolding. As shown in FIG. 1, the system has two arrays of solar panels 16a, 16b, each comprised of a number solar panels mounted on opposite sides of the body. Generally, the photo-active side of each solar panel is facing outwards when the solar panels are retained against the body.

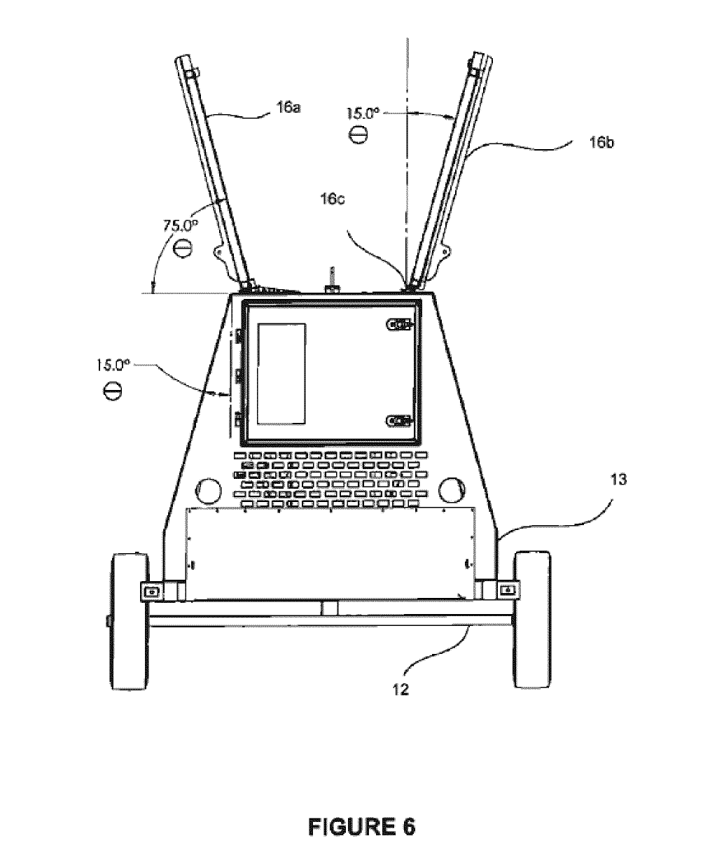

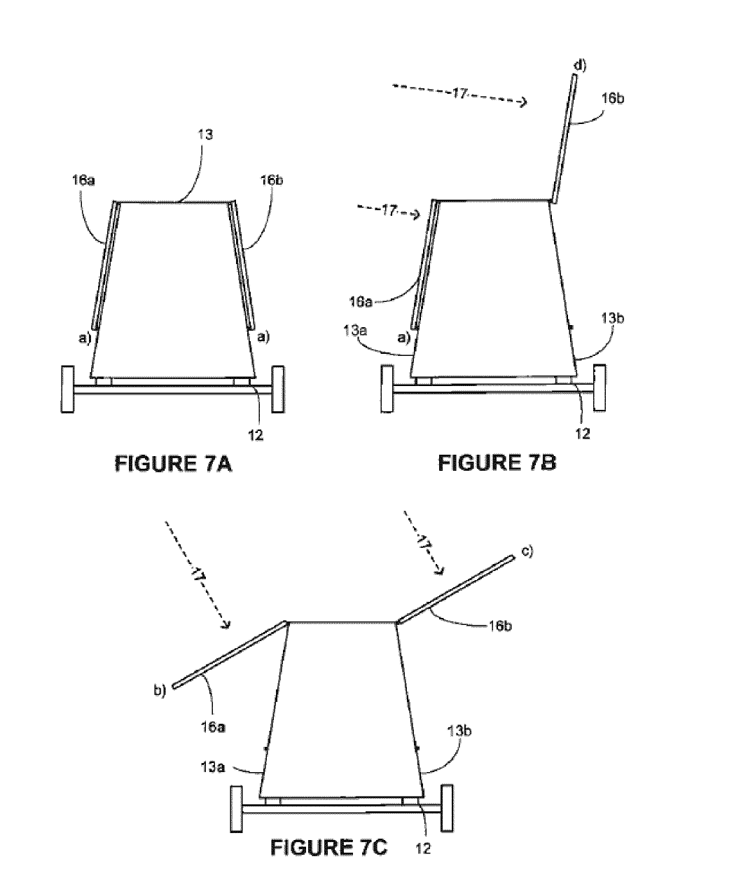

As shown in FIGS. 6 and 7A-7C, the solar panels 16a, 16b can pivot with respect to the body 13 about a horizontal axis via a pivot member 16c between a fully retracted position a), a fully extended position d) and intermediate positions b) and c). In some embodiments, the solar panels may be pivoted and locked at set increments, e.g. every 10 degrees, between positions a) and d) by various support and locking systems as known to those skilled in the art. In some embodiments, the system includes one or more actuators 17 that enable the operator to manually extend and retract the solar panels to any desired angle.

In a preferred embodiment for cold weather climates, opposite sides of the trailer body 13 are at an angle θ with respect to vertical in order to reduce snow accumulation on the trailer body and the solar panels when they are in position a) and to enable orientation to a low sun angle to the horizon in high latitude climates. The optimal snow deflection angle for 0 is approximately 15°, however in other embodiments the angle θ may be from 0 to 45°. FIGS. 6 and 7A-7C illustrate the solar panels as being pivotable approximately 150° between position a) and position d) which represents the desired orientation range for most deployments. In other embodiments, the solar panels may be pivotable more or less than 150° if required or preferred for a particular deployment.

Referring to FIGS. 7A, 7B and 7C, various orientations of the first and second solar panels 16a, 16b are illustrated to demonstrate how solar energy can be most effectively captured based on the angle of the sun relative to the horizon. In high latitude climates, in the winter months, in the northern hemisphere, FIG. 7B may be the desired setup due to the reduced daylight hours in which the sun appears to hug the southern horizon. During these times snow fall would not accumulate on the solar panels due to the angle of the solar array. Further, in this embodiment, the angle of the body 13 preserves the life of the actuators or pistons that position the arrays. During setup, the body 12 will be oriented in an east/west alignment such that one side of the body containing an array of solar panels will be oriented to the south (in the northern hemisphere). Thus, a first side 13a of the body containing solar panels 16a would be facing south. A second side 13b of the body would therefore be facing north.

FIG. 7A shows both solar panels 16a, 16b in a storage and transportation position a). FIG. 7B shows the solar panels 16a, 16b, accordingly, in positions a) and d), used to most effectively capture energy from the sun's rays 17 when the rays are at a low angle to the horizon, such as at high latitudes (generally 50° or above) and/or in the winter season. FIG. 7C illustrates the solar panels 16a, 16b, accordingly, in positions b) and c), used when the sun's rays 17 are at a higher angle to the horizon, such as at mid-latitudes or in the summer season at high latitudes. As such, in some embodiments, the operator will, based on the knowledge of the latitude and time of year, deploy the solar panels such that the solar panels are oriented at an angle as close to 90 degrees to the incident light as possible. In the winter months, when the sun is low to the horizon over the entire day, generally little or no adjustment of the solar panels would be required during the day. During longer days, it may be preferred to set the solar panels for the mid-morning and mid-afternoon sun angle such that the average incident angle during the course of the day is close to 90 degrees.

In another embodiment, the solar panels may be mounted to a solar sensing device such as a solar tracker 36b (FIG. 13) that will automatically orient the panels to the optimum position, throughout the day, week or month that allows the greatest solar input to the system. A solar tracking system may also be integrated with a GPS database as described in greater detail below to dynamically move the panels based on geographical location and time of year.

Various solar panels may be deployed as known to those skilled in the art. For example, the system may include 2 arrays containing 4 to 12 panels with a 100 watt rating each. In other embodiments there may be 1 or more arrays with solar panels rated for 100 to 500 watts each. Solar panel footprint, shape and power rating will consider any or all of the following: a calculation of solar availability, ICE size, load drawn by the LED lights, energy management methods, ICS function and/or acceptable levels of annual fuel consumption, among other factors. Typically, the smaller the solar footprint and greater the LED draw, the more fuel must be consumed.

### Wind Turbine

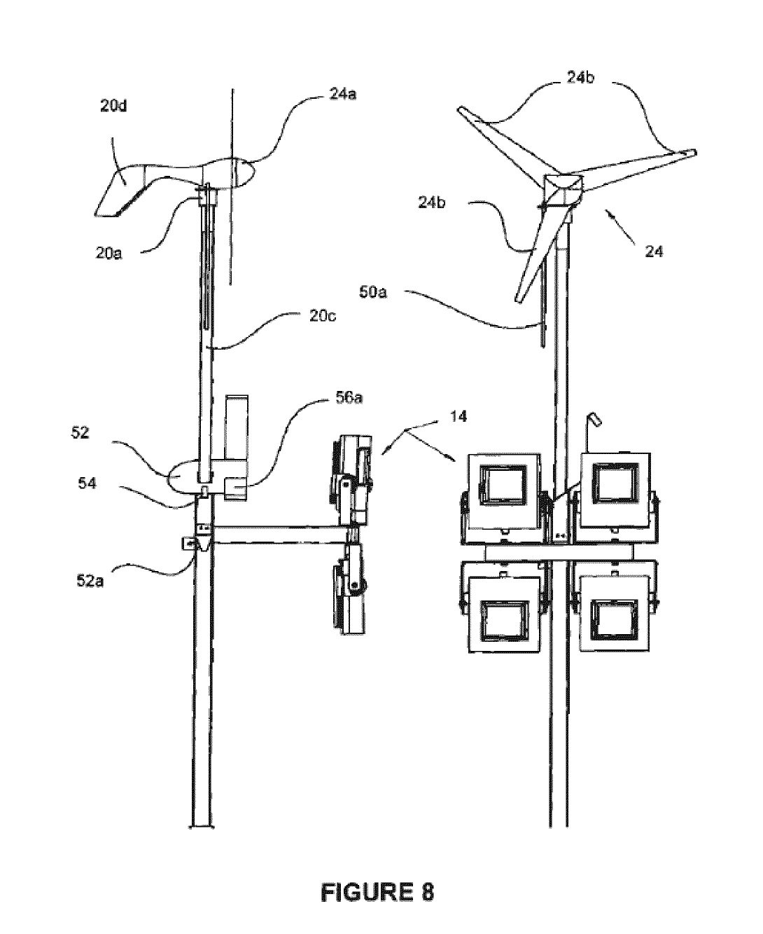

In one embodiment shown in the figures, a wind turbine 20 is configured to the body 13 to capture wind power for the light tower system 10 (see FIGS. 4A, 4B, 5A, 5B and FIGS. 8-11. The wind turbine preferably includes a shaft 20c that is telescopically connected to the mast 27 to enable the wind turbine to move between an erected position as shown in FIG. 8 and a retracted position as shown in FIG. 11.

Referring to FIG. 8, the wind turbine 20 comprises a rotor 24 connected to a supporting member 20a, the rotor having a hub 24a and blades 24b that rotate in the wind with respect to the supporting member. The supporting member is connected to the shaft 20c via a yaw bearing or similar device that allows the supporting member and rotor to swivel around the shaft. A wind vane 20d connected to the supporting member causes the rotor to orient itself with respect to the shaft to most effectively capture wind energy based on the current wind direction. The wind turbine includes the necessary components and circuitry to convert wind energy into electricity, including an electrical generator, gearbox, control electronics, etc. (not shown). It will be appreciated that the wind turbine electrical generator may comprise a direct current power generator configured to generate direct current power directly from the mechanical energy generated by the wind. This may be advantageous for charging the battery and/or providing DC power to any DC loads (e.g. the lighting system and/or any external DC loads).

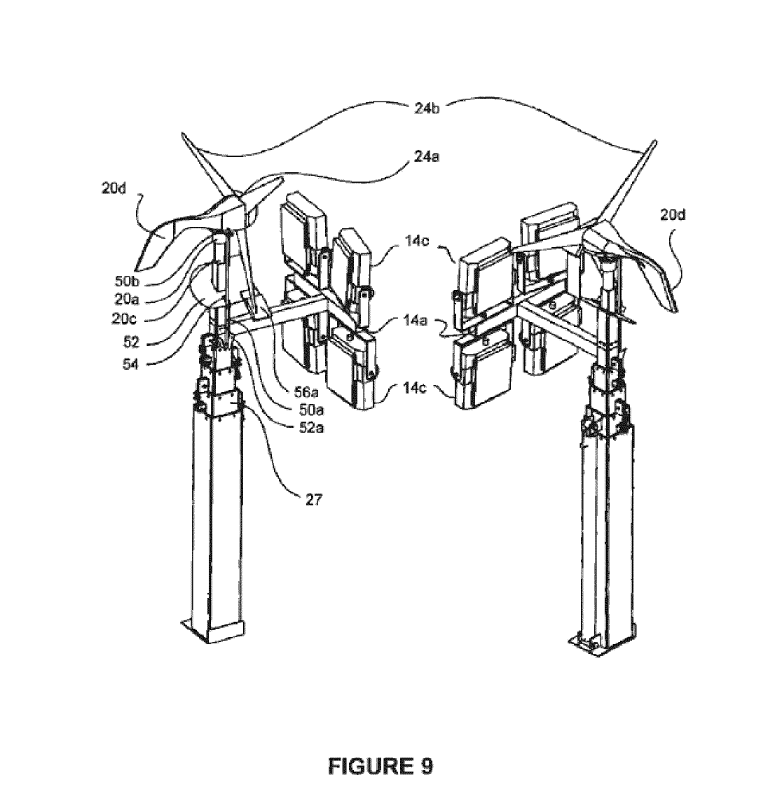

The wind turbine includes a number of features for easy and/or automated and/or one-touch deployment and retraction. These features are best shown in FIGS. 8 to 11, as the wind turbine moves from full extension (FIG. 8), to full retraction (FIGS. 9-11).

Referring to FIGS. 8 and 9, the retraction/deployment features include a guide rod 50 and an angled plate 52 having a slot 54 for receiving the guide rod to prevent the wind turbine from swiveling while in the retracted position. A top end 50b attaches to the rotor and the plate 52 is attached to the mast 27. When the shaft 20c is retracted within the mast, a bottom end 50a of the guide rod contacts the angled plate and causes the supporting member 20a and rotor 24 to swivel such that the guide rod enters the slot 54. When the slot receives the guide rod, the supporting member and attached rotor are directed to and locked in a specific orientation, such as a front-facing orientation, preventing the wind turbine from swiveling during storage and transportation. A spacer 52a or other appropriate securing means is fixed to the mast below the slot and plate for receiving, guiding and providing stabilization for the bottom end 50a of the guide rod as it exits the underside of the slot 54.

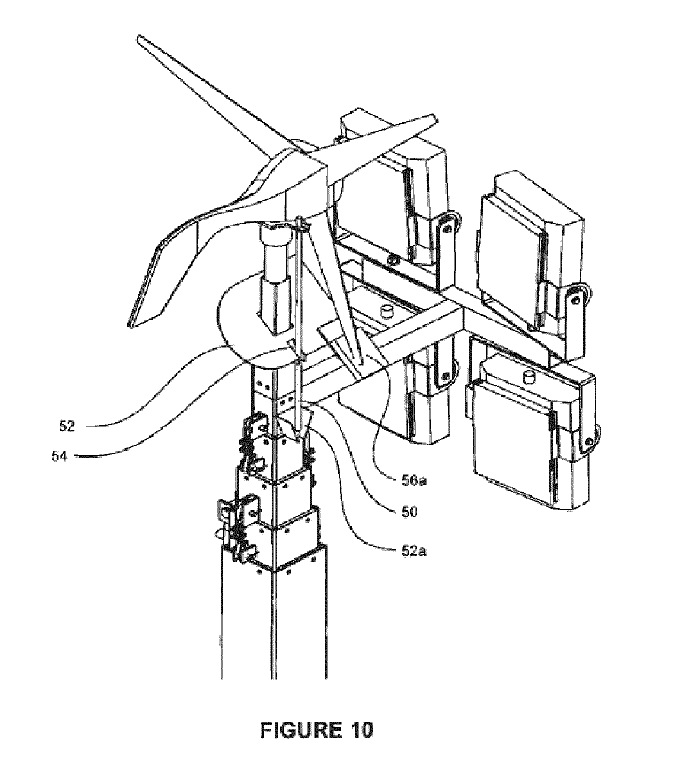

Referring to FIGS. 10 and 11, the wind turbine also includes at least one bumper 56a for preventing the rotor from rotating when the wind turbine is in the retracted position and for providing protection to the blade. The at least one bumper is preferably fixed to the angled plate such that when the shaft 20c is retracted and the guide rod 50 received in the slot 54, one of the blades 24b contacts the bumper 56a, preventing the blade and rotor from rotating. The bumpers are preferably made of rubber or another absorbing and cushioning material in order to absorb shock and prevent damage to the blades during retraction of the wind turbine and during storage and travel.

The wind turbine retraction/deployment components, specifically the guide rod 50, plate 52, slot 54, and bumper 56a, allow for automatic and easy retraction and deployment of the wind turbine. In this embodiment, it is not necessary for an operator to manually rotate and secure the swiveling windmill and rotatable blades during retraction of the wind turbine, as this is done automatically by the action of collapsing the telescopic mast 27. Similarly, during deployment of the wind turbine, it is not necessary for an operator to manually release the retraction/deployment components, as this is also done automatically.

### Deployment and Retraction of System

As configured, a user will deliver a light tower system 10 to a site and orient the trailer or skid, in an appropriate direction for solar energy capture. Typically, either the first side 13a or the second side 13b of the trailer body will be oriented facing south (when deployed in the northern hemisphere). The solar panels and lights 14c are oriented as desired at the site either before, during or after erection of the mast. The wind turbine 20, if present, is released as the mast 27 being extended.

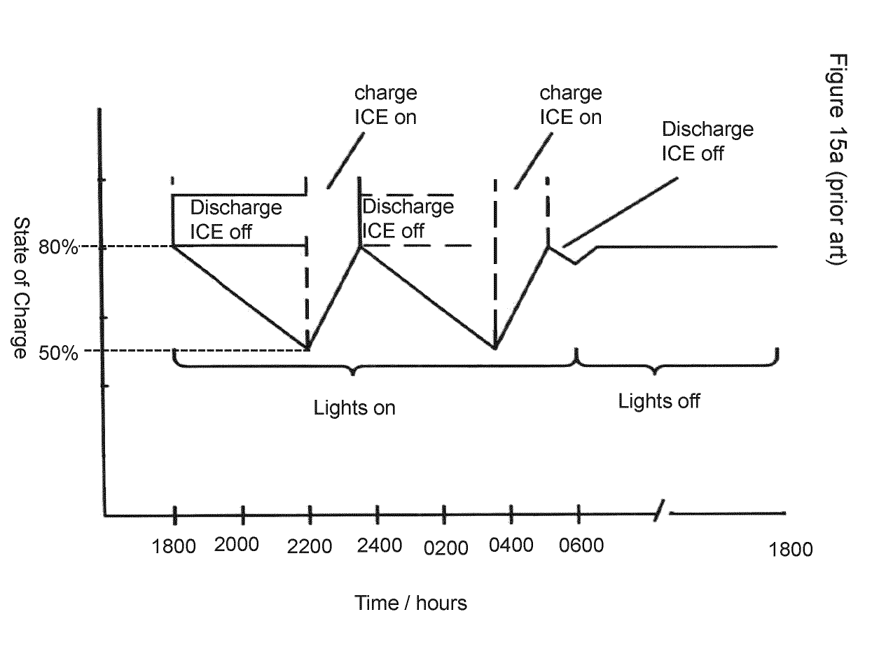

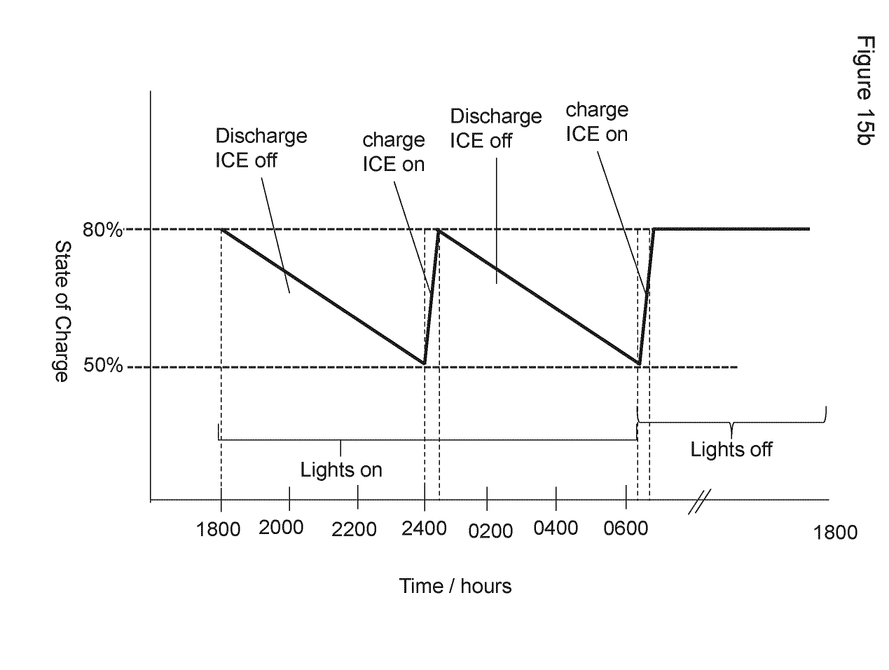

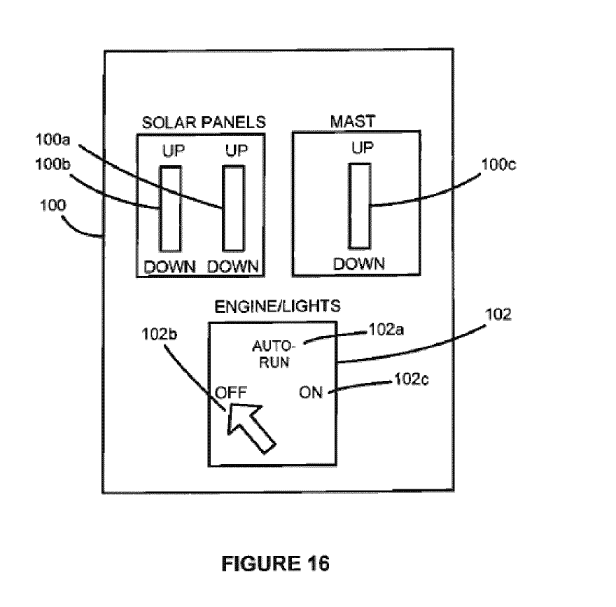

Importantly, in a preferred embodiment as shown in FIG. 16, the system has a control panel 100 for interfacing with the operator and that allows the operator to deploy and activate the system with minimal time and a limited number of physical touches. In some embodiments, the control enables an operator to deploy the system with as few as 3 touches. Advantageously, a 3-touch user control interface system integrated with system components including ICS components, which in some embodiments may include a PLC with pre-set internal logic, minimizes the risk of human error in deploying the system with could cause inefficient operation and/or cause damage to the system. That is, to deploy the solar panels, the control panel includes a first pair of toggle switches 100a and 100b to allow the operator to lift each solar panel to a desired angle (first touch). A second toggle switch 100c causes the extension of the mast (second touch) and a power switch 102 is activated to place the system in an automatic run mode, off mode or manual ICE mode (third touch) explained in greater detail below.

### Internal Combustion Engine (ICE)

The ICE 32, including the necessary associated electronics, direct current power generator and fuel tanks, may be located on the trailer body 13, and is preferably contained within a covered frame 18 to provide weather protection to the engine. The ICE provides energy to: charge the battery bank, power the lighting system and/or generate power for an auxiliary energy draw as needed and as controlled by the ICS 28. In one embodiment the ICE is a diesel-fuel engine which may include a separate starter battery 33 for starting the ICE. While diesel fuel is a preferred fuel for off grid applications, other fuels (e.g. petrol) may be utilized depending on the ICE. The ICE may be rated to over 5 kW (e.g. 8 kW-15 kW).

In various embodiments and particularly for cold climates, the ICE includes a heating system (comprising temperature sensors and a heating element) that operates to maintain the temperature of the ICE in an operating range such that the ICE can start reliably when needed in cold temperatures, without having to keep the ICE idling simply to maintain engine warmth. That is, a heating system may be operatively connected to the ICE and/or a control system for heating the ICE when the ICE is off or heating the ICE prior to the ICS sending a start command to the ICE.

The hybrid lighting system may comprise a grid power connector configured to perform one or more of: connecting the hybrid lighting system to a power grid (e.g. a local DC power grid or national power grid) for receiving and delivering grid power to the light system and/or an external load; and connecting the hybrid lighting system to a power grid (e.g. a local DC power grid or national power grid) for providing power to the grid generated by the hybrid lighting system (e.g. via the ICE and DC generator and/or one or more renewable energy systems).

Various heating systems can be designed with various functionalities as described below.

In some embodiments, a heating system pre-heats the ICE and/or fuel or fuel delivery system in response to a start command given by the operator or by the ICS.

In some embodiments, when an ICE start command is desired and/or signaled, the ICS may, based on the ambient temperature, ICE temperature, fuel temperature, climate or time of year, delay sending the start command to the ICE, instead sending a start command to a heating system allowing the ICE and/or the fuel or fuel delivery system to preheat for either a set time period or a predetermined temperature threshold, at which point when either is reached the ICS or the operator would then send an off command to the heating system and a start command to the preheated ICE.

The ICS may be configured to turn the ICE on and off throughout the entire day and/or night as needed to maintain an optimal ICE temp range, particularly in cold climates to ensure the ICE is always on-call should an operator need to run the ICE in manual mode to produce ancillary power. This operation would pulse the engine and/or the battery bank with electric power and/or thermal heat resulting in a reduced need for an ICE heating system such as an ICE coolant heater or block heater.

In some embodiments, a heat exchanger 44 captures and recycles heat generated by the ICE while it is running. In another embodiment the ICE powers electric heat and/or electric cooling devices, such as a fan, to various system components while running.

In some embodiments the ICE schedule is controlled by components of the ICS such as timers that can be manually set (for a 24 hour cycle or period) by an end user (worker). In another embodiment the ICE schedule is controlled by a programmable logic controller (PLC) or PCB software coding that does not allow for the end user (worker) to adjust the schedule at a worksite. In other various embodiments the ICE schedule is controlled by any combination of timers and PLC. All of the above may be integrated with an ICE autostart or similar functionality provided by a PLC or PCB.

A consideration when choosing the size of the ICE to be used is maximum load for an operator and/or the size of the size and type of the batteries. In a typical deployment, the ICE is sized to power an 8-20 kW generator which sufficient to power most ancillary loads. In some embodiments, a heat exchanger 44 captures and recycles heat generated by the ICE while it is running.

### Battery Storage System

The battery storage system 30, which may or may not comprise a ICE starting battery (ISB) 33, is, in this case, situated on the body 13 within the enclosure 18 and is configured to receive and store energy generated from the solar power system 16, the wind turbine 20 (if present), grid power (if available) and/or the ICE 32. The battery storage system and/or ISB is configured to release the energy to power the lighting system, and/or various components of the ICS and system.

Importantly, the voltage and current ratings of the battery storage system are designed in conjunction with the overall energy performance of the system and with a primary objective of improving the efficiency of fuel consumption for a particular operational situation.

The voltage rating of the battery storage system will typically be designed with a voltage between 12-96V, but preferably between 24 volts and 48 volts, to avoid system power losses due to line loss and to easily integrate with off-the-shelf system components. For example, one embodiment may comprise 8 3.2V lithium ion cells wired in series to give an output voltage of 25.6V. Another embodiment may comprise 8 6V lead-acid batteries wired in two parallel strings of four batteries to give an output voltage of 24V. In some embodiments the battery storage system is sized to 800-900 amp-hours. In other embodiments the battery storage system is sized between 200-1600 amp-hours.

The total current rating of the battery storage system will be chosen in conjunction with the lights, the battery storage system and desired method of battery utilization.

The battery storage system may comprise a 12 volt lead-acid battery (e.g. similar to those commonly used to start an ICE). The 12 volt lead-acid battery may be used as an ICE starting battery.

The battery storage system may comprise a lithium ion battery configured to store electrical power from the ICE. The battery storage system may comprise one or more batteries (e.g. Lithium ion batteries) configured to be able to store power from a charging current with a magnitude which is equal to or greater than that of the maximum battery output current. For example, a 400 amp-hour 24V lithium ion battery bank may be charged with 400 amps (i.e. a 1 C rate) resulting in a 1 hour charge. Indeed, some lithium ion batteries may be configured to accept charging currents which are multiples of their 1 C rate (e.g. the maximum charging current may be up to five times the 1 C rating). For example, a lithium ion 400 Amp-hour battery may provide an output of 400 amperes for 1 hour when discharged at 1 C. Such a lithium ion battery may be configured to be charged at over 1 C. For example, such a battery may be charged at 2000 A (corresponding to 5 C) resulting in the charge time being a fifth of the 1 C charge time (12 minutes at 5 C rate compared with 1 hour at 1 C rate). Increasing the charging rate reduces the runtime of the ICE.

In contrast, some batteries (e.g. AGM batteries) can only be charged with 10-25% of the battery bank current rating (e.g. at between 0.1 C and 0.25 C rate) which means that the ICE must run for a longer time to charge the batteries.

Lithium ion batteries may have a larger useable SOC then other batteries (e.g. a larger range of SOC within the bulk charging phase). For example the bulk phase of a Lithium ion battery may be between 10% and 90% state of charge. Lithium ion batteries may be more efficient at storing charge. That is, a greater proportion of the charging energy may be recovered from the battery. Using such batteries may reduce ICE run time.

In some embodiments the ISB is used to power the heater 26a, the mast, the solar wings and/or components of the ICS.

The battery storage system in some embodiments comprises a battery bank. The battery bank may comprise 400 amp LiFePO₄ battery bank having a battery management system. The Battery Management System (BMS) may comprise a load controller (e.g. a cell loop) configured to activate a contactor to remove loads and/or battery charging in certain conditions, for example when the battery bank is frozen in which case its not ideal to charge.

An embodiment of a battery bank may comprise 8×3.2v 400 ah LiFePO4 in series for a 24 volt nominal 400 ah bank. Each cell is individually monitored for LVC and HVC (Low Voltage Cutoff and High Voltage Cutoff). In this case, if any cell goes beyond LVC 2.75 volts or HVC 3.625 volts, any individual monitor may break the continuous signal loop that will trigger a contactor to open to prevent battery damage and/or thermal runaway.

In some embodiments, parallel with a contactor is a 400 amp diode to allow lighting and battery discharge after cold battery bank signal has opened the contactor. This may allow a draw on the battery bank but does not allow it to charge until its temperature increases above a low temperature threshold, for example 2° C. or above freezing. The diode rating may correspond to the battery current rating.

### Battery Heating System

The hybrid lighting system may comprise a battery heating system operatively connected to the battery storage system for heating the battery storage system to maintain the battery storage system within a temperature range.

The battery storage system may comprise thermally insulated batteries.

The hybrid lighting may comprise a heat exchanger connected to the ICE for capturing and recycling heat released from the ICE for warming the battery storage system and/or the ICE.

For cold climate deployments, the system will preferably include at least one battery heating system 30e (shown in FIG. 13) to improve the efficiency of operation of the system batteries. By maintaining battery temperature within a preferred range, both SOC efficiency and cycle life can be improved. The battery heating system may be any one of or a combination of an electrical heating system such as an electrical element or battery blanket, compartment insulation that insulates the batteries from the exterior allowing the thermal heat from charging to remain in the battery compartment without the need for external heat input and/or a coolant heating system that circulates ICE engine coolant around the batteries. In warmer climates, the system may be configured to include a ventilation system including a fan to assist in ensuring that the battery temperatures do not exceed recommended operating temperatures. Each of the heating systems will use appropriate AC or DC power managed through the ICS.

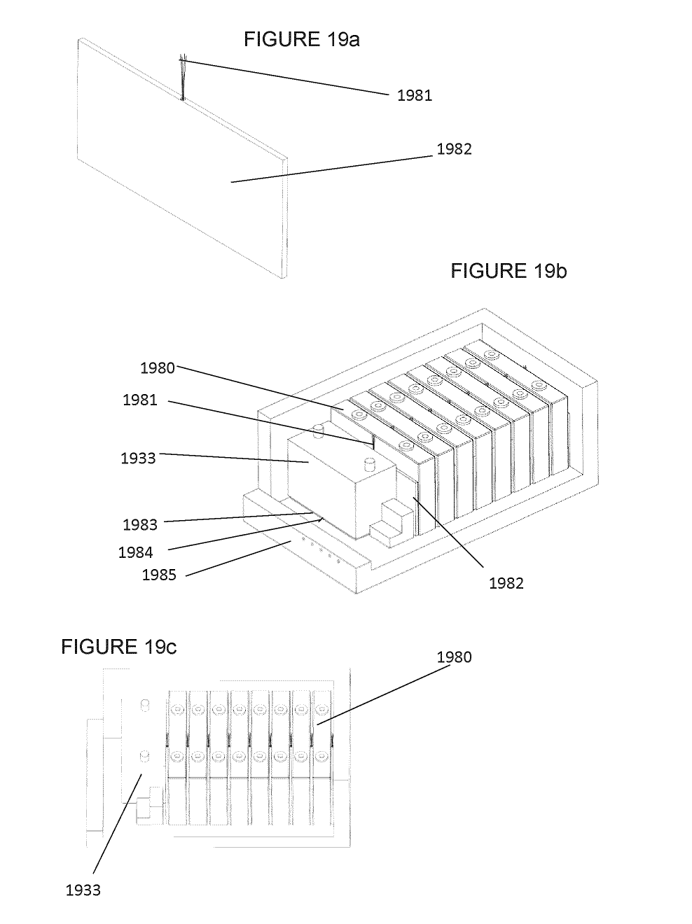

A battery heating system FIG. 19a-19c may comprise one or more thermally conducting plates 1982, the thermally conducting plates being configured: to be in contact with or close proximity to the batteries 1980; and to receive and disperse heat from a heating element 1981. The thermally conducting plates may comprise a metal plate. The metal of the metal plate may comprise, for example, aluminum or copper. A thermally conducting plate may comprise thermal paste sandwiched between two metal plates (e.g. comprising aluminum) and/or between the plate and the adjacent battery. Thermal paste may comprise a polymerizable liquid matrix and large volume fractions of electrically insulating, but thermally conductive filler. Matrix materials are epoxies, silicones, urethanes, and acrylates. Aluminum oxide, boron nitride, zinc oxide, and/or aluminum nitride may be used as fillers.

The heating element may comprise a ceramic heater. The ceramic material may be semi-conductive such that when voltage is applied to it, the power decreases as it reaches a certain temperature according to the particular composition of the ceramic. This may allow the temperature of the ceramic heating element to be self-regulating.

In a typical system, a battery storage system is maintained in an optimal operating temperature range typically in the range of 5-25° C.+/−10° C.

In some embodiments the battery heating system may comprise Aluminum plates (¼″ in thickness) placed in between each battery (e.g. 10 in total). The plate may comprise a 25-watt ceramic heater. The ceramic heater may be placed in a gap (e.g. ¼″) that is filled with thermal paste.

The heater may be powered with the 12v battery but can also be powered by 24v if needed.

The heater may be controlled by the controller as follows:
Step 1: If the battery bank temperature drops below a lower temperature threshold (e.g. 5° C.) a relay enables connection of the ceramic heaters to a voltage supply thereby enabling heating.
Step 2: The ceramic heater will continue to heat the aluminum plates until the battery core temperature reaches a higher temperature threshold (e.g. 20° C.).
Step 3: heaters are turned off via relay when the higher temperature threshold is reached.

### Intelligent Control System (ICS)

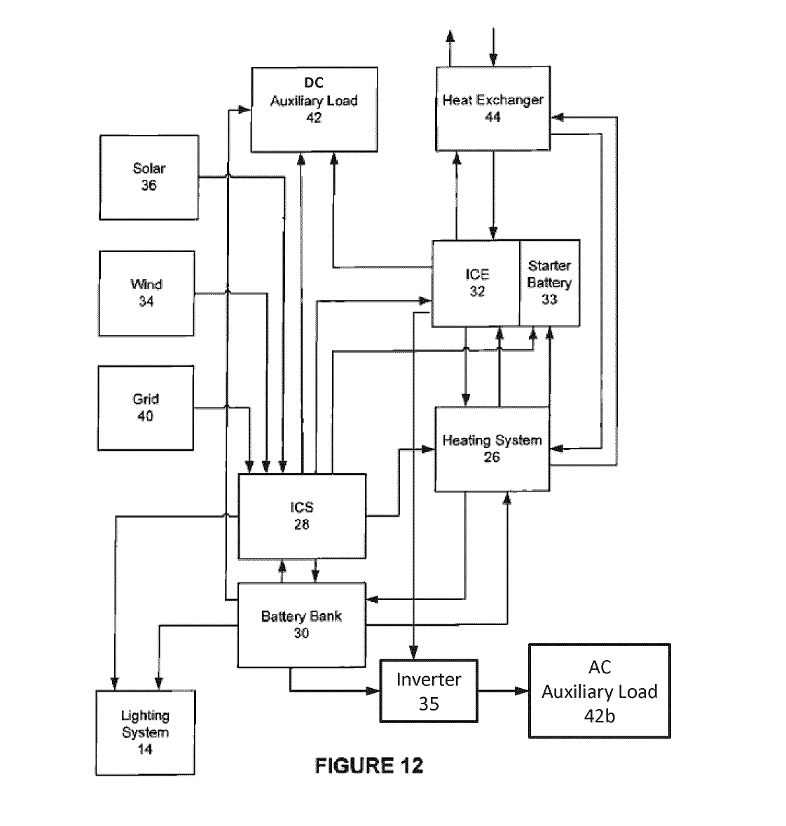

As shown in FIGS. 12 and 13, schematic diagrams of an intelligent control system or controller in relation to other components of the system are described in accordance with one embodiment. The ICS 28 receives inputs from ICE power 32, battery bank 30 and/or grid power 40. Other power inputs can include one or more renewable energy systems including solar 36 and/or wind 34 renewable energy systems.

In this case, the ICS controls power input to the light system 14 for lighting and to the battery storage system 30 as well as power output from the battery storage system. The ICS may also regulate the heating system 26 to turn it on or off when the ICE and/or battery storage system reach certain temperature thresholds or based on programmable timing. Importantly, the ICS (or control system) may be either a single component including various processors and sensors or may be an amalgamation of multiple components with various processor and sensors. In FIGS. 12 and 13, for the purposes of illustration, the ICS is described as a single component but it is understood that collectively the ICS can be configured as multiple integrated components, such as a Programmable Logic Controller (PLC) and/or PCB and/or ICE autostart controller and/or time clock (timer) controller, and/or voltage monitor/controller and/or battery chargers 30f (e.g. comprising DC-to-DC charge controllers) with appropriate algorithm based controller and/or solar charge controller, where functional intelligence is distributed between different components.

The control system may comprise means for:
a. monitoring a current state-of-charge (SOC) within the battery storage system;
b. turning on the ICE to generate electrical power when the current SOC is below a lower SOC threshold or based on an operator programmed start time;
c. turning off the ICE when battery power is above an upper SOC threshold or when an operator programmed runtime has been achieved;
d. directing ICE power to charge the battery system between the lower and upper SOC thresholds or operator programmed runtimes; and/or
e. directing ICE or battery power to the light system if required;
   wherein the control system controls charging of the battery storage system in order to reduce ICE runtime and/or fuel consumption by prioritizing charging of the battery storage system between the upper and lower SOC thresholds

The control system may comprise a battery charging algorithm. The battery charging algorithm may define upper and lower SOC thresholds corresponding to the bulk stage of the battery charging. Bulk stage, bulk charging or bulk stage charging may be defined in one embodiment as the DC generator providing a 1 C charge to the battery bank and/or the SOC or SOC range within a battery, for example a lithium battery. In other various embodiments bulk stage, bulk charging or bulk stage changing may refer to a heavier amp charging condition within a multi-stage battery charging algorithm and/or relate the SOC or SOC range within a particular battery type. The battery charging algorithm may be configured to initiate charging of the battery storage system at a lower threshold within the bulk stage of the battery charging and/or cease charging of the battery storage system at an upper threshold within the bulk stage of the battery charging. That is, this charging cycle would begin and end within the bulk charging phase of the battery. This may increase the efficiency of the lighting system because the ICE may only be turned on to charge the battery storage system at times when the SOC of the battery storage system is such that the battery storage system is particularly receptive to being charged.

In addition, and particularly in a harsh or cold-climate deployment, the management of available renewable energy may be adapted to control heat flow to enable more efficient operation of the system. In particular, as described above, capturing heat and/or minimizing the loss of heat from the system can have a significant effect on battery SOC and overall battery efficiency. In some embodiments, as shown in FIG. 12, the system comprises a battery storage system which may include an ICE starter battery 33. As battery efficiencies generally drop as temperatures drop, in this embodiment, the system comprises a battery heater which is, for example, configured to circulate heat from a coolant heater and/or ICE to the battery storage system and/or starter battery to keep it within a preferred operating temperature range for as much time as possible. In another embodiment, the ICE is configured with a heating blanket or elements that heat the battery storage system when the ICE is running. In another embodiment, an enclosure lined with insulation is sufficient to maintain desired battery temperatures where the thermal energy from charging creates or maintains the enclosure temperature.

As shown in FIG. 12, this embodiment comprises an inverter which is configured to draw DC current from the ICE with DC generator and/or the battery bank. The inverter converts this DC power to AC power for provision to AC auxiliary loads 42b.

Further still, the exhaust system of the ICE may also be provided with a heat exchanger 44 that captures heat from the exhaust system that is channeled or directed to the battery storage and/or ICE batteries and/or ICE engine block.

As shown in FIG. 13, the ICS 28 may receive inputs from a number of sensor inputs to enable effective energy management within the system. In some embodiments, the ICS will monitor auxiliary loads (in the form of DC loads 42a or AC loads which are powered via inverter 35). In some embodiments, the ICS will monitor available wind voltage 34a and solar voltage 36a from the renewable energy systems and/or available grid voltage 40a. The ICS will generally be looking for power sources based on current load demands or time of day. In some embodiments, if there is a lighting load demand, the ICS will initially look to provide that power by available wind power if available. If wind power is not available, the ICS will look to the battery storage system while the battery system has available power above a threshold value. If battery power is below a threshold SOC, the ICS will look to the ICE and/or DC generator for power.

Typically, the ICE will power the DC generator which in turn will charge the battery storage system and/or ISB while simultaneously providing power to the lights and/or other loads such as heaters, PLC, sensors, etc. As described in greater detail below, the ICS will generally control operation of the ICE to reduce fuel consumption and increase battery performance and cycle life. However, it should be noted that the system may enable an operator to keep the ICE operating as long as there is a load draw requiring the ICE to operate. In some embodiments, when the load is removed, the ICS will typically run the ICE to ensure the battery bank has a desired SOC charge in which case the ICS will signal the ICE to auto-off. In another embodiment the operator can manually turn the ICE off once the need for ancillary power has been filled.

The DC generator and ICE may be chosen to improve battery charging performance and to be better integrated with the system. For example, the attributes of the DC generator and ICE taken into account may include the power output of the engine and the charging rate of the generator (e.g. the maximum current from one generator may be 425 A).

In one embodiment, the DC generator works with a Kubota D902 ICE at 3600 RPM or a Kubota D1105 at 1800 RPM producing 8000 watts up to 32 volts.

The apparatus may be configured to have a maximum charging voltage (e.g. 28.9 volts) and to begin charging at a lower charging threshold voltage (e.g. 25 volts which may correspond to 50% SOC).

The generator may be configured to provide different voltages at different current. For example, the generator in this embodiment is tuned to 31.5 volts at 300 amps on a load bank. With a load using the battery bank at 25.3 volts the alternator is then tuned to 325 amps.

In this case, the battery bank is charged at the full 8000 watt capacity till the voltage of 28.5 is reached to allow for battery capacity fluctuations and inconsistencies in battery balancing.

In some embodiments, battery temperature 30d will preferably be monitored to ensure that the battery temperature is maintained within a preferred operating range. On the ICE, the ICE may be provided with an engine block temperature sensor 32b, an ICE oil pressure sensor 32c, a fuel level sensor 32d and/or an exhaust temperature sensor 32e. Each of these sensors provides general information about the operation of the ICE for maintenance and performance monitoring.

In addition, the ICE starting battery system, and/or ISB and/or battery storage system 33 may be provided with a battery voltage sensor 33b, 30b, and/or a battery temperature sensor 33c, 30c to provide both maintenance and performance monitoring. The heat exchanger 44 will typically be configured with appropriate sensors 44a, 44b to monitor the ambient temperature of air entering the heat exchanger and exiting the heat exchanger to the ICE compartment. That is, the ICS will monitor the performance of the heat exchanger to ensure that it is providing a net benefit in overall heat management.

The heater system 26, such as a coolant heater system, may be configured with appropriate sensors to monitor fuel level 26e, coolant level 26f and/or coolant temperature 26g. These sensors provide general information about the operation of the coolant heater system and allow for monitoring of its performance. An ICE heater system may comprise a coolant heater, fuel heater, engine block heater or other ICE heater.

In some embodiments, in response to the ICS detects that battery systems and/or ICE temperatures are dropping below threshold levels, the ICS may be configured to automatically turn on the coolant heater 26a (e.g. to run for a period of time to ensure that the system remains at a preferred temperature). In extremely cold weather conditions this auto on/off may occur several times throughout the day and/or night in order to maintain a minimum threshold system temperature. In another embodiment the ICS may turn on the coolant heater 26a to preheat the ICE when the ICE is to be given the “on” command. In this example the ICS would delay the ICE start by an appropriate time during which the coolant heater 26a would preheat the ICE. In another embodiment the coolant heater 26a may be directed by the ICS to preheat the ICE based on timers and/or time coding, rather than temperature.

In other embodiments, if the ICS detects that battery systems and/or ICE temperatures are dropping below threshold levels, the ICS may automatically turn on the ICE throughout the day and/or night for intervals sufficient to maintain a temperature range that ensures the ICE will reliably start. As discussed below in relation to efficient battery charging, periodic charging and discharging cycles improves the overall efficiency of the system.

In some embodiments, the ICS may include a photocell 36b to enable the ICS to automatically turn the lighting system on or off if automatic operation is desired.

In some embodiments, the system will also monitor auxiliary load current 42a and lights current 14e for calculating power usage rates.

The ICS may be configured control the schedule of the lighting system. This may be accomplished by a PLC or PCB coding and/or timers. The ICS may be configured to allow for an end user to manually control the timing of the lighting system and/or the ICE for 24 hour cycles. For example the user may enable a timer to turn the lighting system on and off each morning and evening consistent with the local sunrise and sunset times. The ICS may comprise a second timer configured to allow the end user to program the timing such that the ICE and lighting system turn on and off daily at the same time or at different times as required by the end user.

In another embodiment a separate timer may be employed allowing the end user to set the timing of a heating system 26a, the lighting system and/or the ICE in a manner suitable to the geographic location and local weather conditions. For example in cold northern climates the system may be designed in such a way that the end user may choose to set timers that permit the heater 26a to turn on 15 minutes before sunset so that at sunset when the light and ICE timers permit them to start, the ICE has already been preheated and the ICE can start reliably without operator involvement. The above are examples and it should be understood that the various timers that make up the ICS can be set in numerous ways that result in desired ICE, lights and heater start and stop times. In a preferred embodiment, for a specific geographic region, a PLC may be employed and programmed based on sunrise and sunset values so that an end user need not manually set timers. This may be advantageous when the lighting system is managed by different users at a given jobsite because it may remove the need for human involvement for light management as the length of day and night change throughout the year. In another embodiment an ICS may be used in combination with one or various timers.

In some embodiments, the apparatus may comprise a GPS receiver or module (e.g. a Venus GPS-11058). The GPS may be integrated into the PCB and comprise a RS-485 interface module. In this case, the GPS outputs a data string that contains at least Latitude, Longitude, Altitude and Date. Once the PCB coding confirms the information in the data string is reliable, a fifth string UTC or other time is added to the usable data string. The PCB coding takes this usable data string and configures it with another algorithm containing global sunrise and sunset time data that can be matched with data points within the usable data string. The ICS or PCB is configured to use these variables to determine sunrise and sunset for any deployment location of the present invention. This process may be repeated daily and will reset the data stored in a CMOS.

That is the apparatus is configured to perform the following steps:
Parse a data string provided by a GPS. The string may comprise additional data and because the data is provided in a predetermined format, the required data may be determined by, for example, counting commas.
Once the required variables are identified they get cached into memory and the processor will continue to parse additional strings, for example 4 more strings, and cache the variables until it has matching sets, for example 4 matching sets. It will be appreciated that different numbers of matching sets may be used.
The 4 matching sets of variables, the Latitude, Longitude and Altitude are paired with system data including time and a solar activity algorithm to determine and use sunrise and sunset times and schedule the lights to turn on and off.

It will be appreciated that, if the GPS is unable to locate a satellite on a particular day, the system may use the last known information or data string until a new GPS signal is acquired.

### ICS Control of the Battery Storage System

As described above, the ICS 28 may be configured to monitor and control the various sub-systems as well as the flow of energy through the system. As noted, the primary objectives are: a) to increase fuel efficiency, b) to manage battery charging to increase fuel efficiency and optimize battery life, c) to ensure managed delivery of energy to the load and d) to reduce ICE runtime.

Generally with regards to battery life, battery life is improved by managing the charging and discharging of the batteries such that the rates of charging and discharging are maintained within desired ranges. In a typical battery bank, the efficiency of charging will depend on the SOC of the battery and the rate of charging. That is, for a given available current at a charging voltage, the efficiency of charging when compared to fuel consumption and ICE runtime will vary based on the SOC, the SOC being determined by voltage sampling, amp in/out calculations or other method of determining a battery banks remaining energy or percentage of remaining charge known to those skilled in the art. In addition, depending on the design of the battery, the cycle life the battery will be affected by the charging and discharge rates to which the battery is subjected.

For example, batteries designed for deep-discharge will typically enable a lower current to be drawn from the battery to a lower SOC. If the rate of discharge is maintained within a preferred range and the battery is charged at a preferred rate, an optimal number of charge cycles will be realized. Similarly, high-power batteries designed for delivering high currents may have their life compromised if the battery is repeatedly allowed to discharge below a recommended SOC.

Further still, depending on the SOC the rate of charging will vary for a given input voltage and current. That is, in a typical battery, for example AGM batteries, the optimal charging current will vary for different SOCs where charging can be characterized as a) bulk phase charging, b) absorption phase charging and c) float phase charging.

Generally, bulk phase charging provides the most efficient and the most rapid rate of charging (i.e. where the battery is accepting the highest current). The precise SOC boundaries for bulk phase charging will depend on the battery type. For example, a lithium ion battery may have a larger bulk phase SOC range than a lead acid battery. Charging beyond the bulk phase will result in a diminished rate of charging with the battery accepting a lower amount of current resulting in greater charging time, and longer ICE runtime, for a lower percentage of SOC increase. Rate of charging will diminish further during the float stage where the battery can only accept a still smaller amount of current.

In some embodiments, the majority of time spent charging is limited to the bulk phase of the battery charge algorithm which can be effective in minimizing ICE runtime while optimizing battery charging rate. In this embodiment a maintenance cycle to periodically bring the SOC to 100% can increase battery life and other battery performance characteristics.

Importantly, and in accordance with the invention, the ICS balances the above system parameters with the overall operational objective of reducing fuel consumption at a job site. That is, the ICS receives instantaneous data from the system to monitor present system status and determine short-term actions while also undertaking longer term actions to improve long-term operation and health of the system.

The control system may be configured to control the current provided to the battery for charging and/or the current taken from the battery based on the state of charge of the battery and/or the temperature of the battery (e.g. measured by a thermometer such as a thermocouple). For example, the control system may be configured to reduce (e.g. by lowering or stopping) the charging current when the State of Charge has exceeded a predetermined level; and/or reduce (e.g. by lowering or stopping) the current taken from the battery when the State of Charge has dropped below a predetermined level. This may be particularly important for lithium ion batteries which may experience thermal runaway if overcharged and/or over-discharged.

The ICS may be configured to manage daily charging of the battery storage system depending on the time of day and the anticipated or actual load and longer cycle charging to optimize battery cycle life. The charging regimes are generally defined as a daily cycle and maintenance cycle.

The daily cycle or bulk phase charging cycle, generally charges and discharges the battery storage system within a range of SOCs in conjunction with the daily load on the system. Typically, during the daily cycle, the ICS will initiate charging of the battery storage system when the SOC drops below about 10%-50% and shut-off charging of the battery storage system when the SOC reaches about 80-90%. In a typical scenario, the daily cycle will include a time during which the battery storage system is discharging due to the load (time period based on actual load) followed by a 0.5-2 hour charging cycle. The daily cycle may repeat several times over the course of a day or designated period of time within a day dictated by the ICS and/or its coding.

The maintenance cycle, required more for AGM than lithium batteries, generally charges the battery storage system to full capacity after a longer period of time. The maintenance cycle will typically fully charge the battery storage system over a 2-8 hour charging cycle and will occur periodically, for example every two weeks of operation or after roughly 20-100 charging cycles, depending on time of year and solar availability. Depending on the battery storage system, prior to commencement of the maintenance cycle, the SOC may be taken to a lower SOC than during the daily cycle.

Importantly, during the daily cycle, as the electrical conversion rate of consumed fuel is more efficient (up to about 95% SOC), excess fuel is not being burned running the ICE. That is, during the daily cycle, a greater percentage of the available ICE power is used to directly charge the battery storage system meaning that for a given liter of fuel consumed, the system receives the greatest quantity of power. Said another way, by only running the ICE when the battery SOC is in a state where the DC generator can input current in the bulk phase, as opposed to the absorption or float phase, the system receives maximum energy from the conversion of fossil fuel to electrical energy. In contrast, during the maintenance cycle of AGM batteries, where the battery storage system is charged to 100% SOC via up to all three phases of charging, the conversion rate of a liter of fuel diminishes as the engine may be essentially idling during the absorption and float phase requiring a smaller amount of the available ICE power. If one were to charge the battery storage system to 100% each time the battery storage system SOC dropped below 50%, the ICE run time would have to be significantly increased resulting in greater consumed fuel. In some embodiments, during daylight hours when the battery storage system is not under draw from the lights, the ICS will not allow the ICE to run, allowing the solar input to dominate the battery storage system charging. In another case it is advantageous to cycle lithium batteries between, for example, 10% and 90% SOC during a time period in which the battery storage system is under draw.

As shown in FIG. 15a, a representative charging cycle (pulse type charging cycle) of the battery storage system of the applicant's previous system described in PCT/CA2013/000865 is shown during a typical 12 hour period of darkness where the ICE may be required. In this system, an alternating current generator is used in conjunction with a current controller and Absorbent Glass Mat (AGM) Batteries. As shown, if darkness begins at 18:00 hours and lasts until 06:00 hours, in some embodiments it is preferred that the batteries are allowed to discharge to about 10-50% SOC and then re-charged to about 80-100% SOC over an approximate 0.25-2 hour charging cycle. Thus, if the batteries are at or about 80% SOC at 1800 h and the lights are turned on, the lights will draw power down from the batteries for a period of time (possibly about 4-8 hours based on load). When the batteries reach about 50% SOC, the ICE will turn on to charge the batteries and simultaneously power the lights. When the batteries reach about 80% SOC, the ICE will turn off and the cycle is repeated until morning when the lights are turned off.

FIG. 15b is a graph showing state-of-charge vs. time of a battery bank in accordance with an embodiment according to the present disclosure. In this case, the system comprises Li-ion batteries and LED lights. For ease of comparison, in the example shown in FIG. 15b, the same SOC thresholds are used for the charging-discharging cycles as those used for the system of FIG. 15a. In this embodiment, in contrast with that of FIG. 15b, the lighting system uses a DC generator. Because the rate of charging for Li-ion batteries is much faster and current is controlled in a different way, the charge time is shorter than for the embodiment of FIG. 15a. In this case, the embodiment is configured to provide 6-hour ICE off time (during discharge) and 30 minute ice on time (for charging). This shows that the ICE run-time may be reduced compared with the embodiment of FIG. 15a.

Importantly, this pulse type of cycling of the battery ensures that the ICE is run for the minimum amount of time during the night to provide sufficient energy for both charging and/or powering the load. For example, in the example shown in FIG. 15a, two charging cycles are completed based on a 6 hour discharge (e.g. 18:00 to 24:00) and 0.5 hour charge cycle (e.g. 24:00 to 24:30). This is a better lights-on to ICE-runtime ratio than the system of PCT/CA2013/000865. As a result, fuel consumption is reduced.

In some embodiments, the charging intervals may either be controlled manually via a manually set controller(s) such as a timer, in conjunction with an ICE autostart and/or voltage monitor, or in a preferred embodiment, controlled by a PLC via internal time coding combined with an ICE autostart with voltage monitoring functionality. Should the ICE experience a mechanical failure preventing it from turning on and providing power to the battery bank at the lower SOC threshold, the ICS may be configured to gradually reduce power to the lights, dimming them over time, as a means to extend the range of time light is provided until the battery bank goes dead.

It will be appreciated that Li-ion batteries may be charged in the bulk regime across a much greater SOC than AGM batteries which will further improve efficiencies.

As noted, a maintenance cycle may be run on a regular basis where the ICE is run sufficiently long (typically 4-8 hours for a lead-acid or AGM battery system) to fully charge the battery storage system to 100% SOC. Also, where charging power is provided by renewable energy sources, the charging may continue to SOCs higher than the ICE cut-off threshold (e.g. to 100% SOC). Similarly, where charging power is provided by renewable energy sources, the system may be configured to allow charging of the batteries regardless of whether the SOC is below the ICE start threshold.

In other embodiments, different maintenance cycle charge times are programmed into the ICS depending on the month of the year. For example, in high latitude climates where solar in plentiful in the summer and scarce in the winter, the ICS may allow a 3 hour maintenance cycle in the summer and a 7 hour maintenance cycle in winter. Alternatively, it may be advantageous to allow the DC generator to charge until a threshold voltage is achieved (e.g. to a 100% SOC) at which point the ICS will send a stop command to the ICE.

In other embodiments, the maintenance cycle, DC generator run timing and/or voltage parameters all consistent with a pulse type charging technique may be manually controlled and/or controlled by automated coding that suits a specific need.

Other charging regimes may be implemented based on the particular performance characteristics of a battery storage system and/or DC generator. For example, some battery systems may enable efficient bulk charging over a greater range of SOC (e.g. 30-80% SOC). Similarly, a maintenance cycle may include discharging the battery to a lower SOC (e.g. 0-10%) prior to fully charging. In another embodiment, if fewer battery charging cycles in a given timeframe are desired, the battery storage system may be charged by a method wherein the battery storage system is permitted to charge and discharge between a low threshold, for example 20% SOC, and an upper threshold of between 80%-100% SOC. In this embodiment there may only be 1 charge per day and the maintenance cycle may not be necessary. In this embodiment the ICE may be permitted to turn on with the lighting system at night and run for a programmable period of time or until an upper SOC threshold desired by the operator has been met.

### Coolant Heating System (CHS) and Heating System

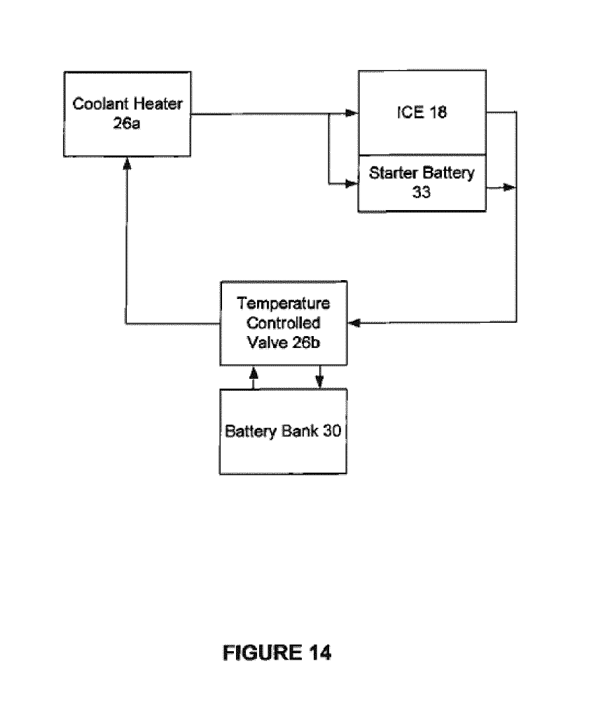

In some embodiments for cold climates, and referring to FIG. 14, the system includes a coolant heating system (CHS) 26 that includes a coolant heater 26a for maintaining a starting temperature of the ICE 32. The CHS creates and circulates warmed coolant through the ICE block, particularly when the ICE is not running and is not generating any heat of its own, thereby maintaining a preferred engine starting temperature within the ICE and enable the ICE to start when in cold ambient temperatures. This allows the ICE to be turned off when it is not needed to generate power instead of being kept idling, thereby reducing fuel consumption in colder climates and the noise associated with running the ICE more than is otherwise needed when compared to a warmer climate. The CHS generally operates by burning a small amount of fuel, relative to the fuel consumption of an idling ICE, sufficient to heat coolant. This preheating process prevents excessive idling of the ICE in cold weather simply to keep the ICE on-call.

In some embodiments, the CHS 26a may also circulate warmed coolant to the battery bank 30 when needed. In this embodiment, a 4-way valve 26b controls the flow of coolant between the coolant heater and battery bank, thereby maintaining the temperature of the battery bank within an optimal operating range. In some embodiments, the 4-way valve includes a temperature-controlled switch that closes or opens the valve based on a pre-determined minimum temperature threshold for the battery bank, such as 10-40° C.

### Other Intelligent Control System Features

The ICS may have a variety of features providing particular functionality that may be applicable or beneficial for particular deployments.

The hybrid lighting system according to any preceding claim, wherein the portable hybrid lighting system is configured simultaneously to provide, from the battery storage system and the direct current power generator, direct current power to an external DC load (e.g. a single external DC load). The external DC load may comprise, for example, an external battery charger (e.g. for charging portable-tool batteries), a laptop computer; or an external light.

In some embodiments, the ICS regulates the CHS to turn it off when the temperature of the circulating coolant and/or the ICE block is higher than a pre-determined temperature range or on when the temperature of the circulating coolant is lower than a predetermined temperature range, such as −5° C. to +5° C. In this embodiment the ICS may rely on a temperature switch to indicate the state of ICE block and/or ICE coolant temperature.

In some embodiments, the ICS is configured to only engage the CHS prior to sending a start command to the ICE.

In some embodiments, when an ICE start command is desired and/or signaled, the ICS may, depending on the ambient temperature, ICE temperature, climate or time of year, delay sending the start command to the ICE, instead sending a start command to the heating system allowing the ICE to preheat for either a set time period or a predetermined temperature threshold, at which point when reached the ICS or the operator would then send an off command to the heating system and a start command to the preheated ICE.

In some embodiments, the CHS is controlled by a temperature switch. In this embodiment the ICE is constantly maintained within a predetermined temperature range so that the ICE is always “on call” for an ICE start command, regardless of the ambient temperature.

In some embodiments, the operator may manually start the CHS prior to starting the ICS. In another embodiment the operator may control a programmable time clock or timer that controls the starting and stopping of the CHS.

In various embodiments, the CHS may be a Webasto™ or Espar™ brand, sized according to the ICE.

### Battery Charging

The DC generator may be configured to supply a voltage to charge the battery storage system directly. That is, the power generated by the DC generator may be supplied directly to the battery storage system without intermediate components configured to change the voltage and/or current.

In other embodiments, it will be appreciated that the electrical parameters of the power generated by the DC generator may be changed before being supplied to the battery storage system. For example, DC-to-DC charge controllers may be configured to control the voltage and/or current provided to the batteries from the generator. The DC-to-DC charge controllers may comprise on or more DC-to-DC converters (e.g. switch mode converters). In addition the ICS may, in some embodiments, be configured to control when and how the DC generator provides energy to the battery storage system and will generally utilize a 2-stage or 3-stage, charging method or algorithm.

During bulk stage charging lithium batteries, the DC generator will input current to the batteries close to their maximum input rating (which for lithium ion batteries may be greater than the batteries' 1 C rate—e.g. charging at 2 C rate such as 800 amps for a 400 amp-hour battery). In another case, during the other two stages required for AGM batteries (i.e. the absorption and float stages), the DC generator may be controlled to input fewer amps into the battery per hour of ICE runtime.

Furthermore by managing the DC generator in the above described manner, it allows scalability of lighting on a given system. For example if a user were to need more light, the system could supply the additional amp draw to the new lights resulting in an increase in engine run time automatically. Whereas if the ICS was designed with components that allowed the engine run time to be manually set by a user, the user would have to understand how to calculate the new engine runtime and/or solar inputs and/or battery charging algorithms along with other system factors to ensure the batteries would not become drained for lack of ICE runtime and/or insufficient battery charging. However, in another embodiment where scalability, flexibility or reduced manpower is less of a concern, the ICS may be designed with controllers that utilize dials, switches, buttons, gears, timers, digital timers or other digital controllers all of which would allow the operator to manually code the system functions based on a known draw and other known characteristics. In another embodiment, the ICE run schedule can be a combination of manual coding and automatic SOC sensing.

### Geographical Functionality

In some embodiments, the lights turn on/off based on ICS coding of sunrise/sunset values for different geographic areas. This saves the operator from having to manually set the light schedule as the length of day and hours of sunrise/sunset fluctuate throughout the year. In some embodiments, the system includes a master global sunrise/sunset algorithm coded in the ICS. In some embodiments, the operator may use manual toggle switches dials, gears or the like to let the ICS know which light on/off schedule to use. In another embodiment the ICS receives feedback from an onboard GPS which then controls the light on/off schedule according to the need of that geographic area. The auto-start function for the ICE and the coded light on/off schedule controlled by the ICS is used to reduce operator involvement in managing the system. In other preferred embodiments more thoroughly described above, certain data within a GPS derived data string is paired with an algorithm to output the lighting schedule automatically based on a system deployment location.

### Auxiliary Power

If auxiliary power requirements exist at any time, in some embodiments the ICE would automatically be turned on by the ICS to provide the auxiliary power that may be required through the battery bank circuit and/or to an AC and/or DC power outlet on the system. In another embodiment an operator can manually control the ICE by switching the ICS from auto mode to a manual mode to provide the auxiliary power.

Preferably, the system will operate to reduce the amount of time the ICE may be run during nighttime hours so as to reduce the noise impact at the site where there may be workers may be sleeping nearby.

Importantly, the system by using a plurality of energy inputs, and prioritizing based on renewables, can operate more efficiently with less servicing requirements in terms of both fuel and personnel time.

### Location Device to Determine Lighting Schedule:

Certain embodiments may include a control system comprising programming, sequences and/or codes that convert a GPS locator signal input into a lighting schedule (e.g. the schedule including times when the system is turned on and/or times when the system is turned off). Such a control system may be included as a means of global distribution of the present invention without the need to program a lighting schedule at the manufacture stage. For example, an operator may receive a system in the middle of south America or Africa with the same factory source code. Upon arrival in both cases the operator would initiate an action, for example press a button that would allow the newly deployed (or re-deployed) system to locate its latitude and/or its longitude (or another location indicator). Once the system control has established is location coordinates it may then search its code for the lighting schedule appropriate for its location. The lighting schedule may be derived from code or data relating to solar activity including sunrise and sunset information for various geographic locations around the globe.

### Network Integration

In some embodiments, the system will also include a modem 62 or GPS (not shown) for enabling data being collected from a system 10 to be sent to a central monitoring computer 60. The central computer may allow multiple systems 10 to be networked together at a single job site thus enabling personnel to monitor the performance of multiple units a job site. Centralized monitoring can be used for efficiently monitoring fuel consumption rates for a number of units that may be used for re-fueling planning and fuel delivery scheduling purposes. Similarly, ICE engine, coolant heater, wind tower, solar cell and/or light tower performance can be monitored for performance and maintenance reasons.

Data collected by a job site computer 60, modem 62 and/or GPS may also be reported back to a central system over the internet and/or cell towers and/or satellites for the purposes of monitoring a fleet of equipment across a wide area network. In this regard, each system may also be provided with GPS systems to monitor the location of equipment and transmit data.

The system may comprise a transmitter configured to transmit information via a network to a remote location. For example, the transmitter may allow emails to be automatically sent from the system to a remote location, the emails comprising operational data relating to the system.

For example, the engine controller will attempt to start the engine a predetermined number of times (e.g. 3 times) and will verify that the engine has started (e.g. based on the oil pressure switch). If the engine has failed to start after the predetermined number of times, the PCB or controller will send a signal (e.g. a 12V signal) to an asset tracker input, that in turn sends and email notifying the user of a failed start.

The PCB or controller may be configured to record the duration of engine use and send a signal when the duration exceeds a predetermined threshold. For example, the PCT may use an internal clock to count the continuous ignition time on, and the processor subtracts the variable from the constant engine oil change interval. Once the remainder total reaches 250 hours from the constant an input on the asset tracker is activated via the PCB or controller and an email or other message is sent to the user notifying the user that it is time to change the oil.

Signals may be generated based on Battery Managements System status. For example, BMS Failure occurs (and signals are generated) when any of the following conditions are met: if any battery cell reaches below 2.75 volts or measures above 3.625. If this occurs and email or other signal may be sent to the user.

Cumulative engine runtime, low fuel, and other system health issues may also be emailed the user.

### Other Design Considerations

It should be noted that in some sun-rich climates, with a large solar panel footprint, it is possible for the lighting to be self-sufficient year round with no fuel consumption; however this typically only occurs when power consumption related to LED lighting is reduced to a value that may not provide comparable light output of a standard metal halide (MH) light tower. With a reasonable sized solar footprint for a portable light tower, if LED wattage is sized to provide comparable light to a standard MH light tower, there must be an ancillary power source (i.e. ICE) to supplement the annual need. Further, when choosing LED wattage, the amount of light provided by the LED must be balanced by acceptable levels of reduced fuel savings. For example, it may be more appropriate to choose less lighting to save more fuel and ICE run time, whereas in another case it may be that more lights are needed that will result in less fuel saving than in another case, but still more fuel savings than using MH bulbs on a standard light tower.

It is also preferable to utilize a system that can provide fuel savings without sacrificing lighting needs. For example, if similar light to a 4,000 watts MH light tower is provided by 1,000 watts of LEDs with approximately 95% reduction in power draw when combined with a typical solar and/or wind power input for a geographical location, this can result in a reduction in fuel consumption, maintenance cost and system wear of 60-95%.

### User Interface

In some embodiments, a user interface 100 is provided that simplifies the deployment and operation of the system. As shown in FIG. 16, after orienting the system at a job site, the operator can fully deploy and operate the system with a minimal number of physical touches to the system. In some embodiments, the entire system can be operated by a system of three switches called the 3-Touch Setup Interface (3TSI). As shown in FIG. 16 the interface includes solar panel switches 100a,b, mast switch 100c and ICE/lighting control switch 102. Solar panels can be deployed and adjusted by simple toggle switches 100a,b or in another embodiment the solar panels can be controlled by 1 toggle switch or in another embodiment by several switches allowing for various axis tilting to align the solar panels with the sun. The mast is erected by a similar toggle switch 100c. The ICE/lights can be in one of three modes of operation, “off”, “auto-run” where the ICS fully controls the operation of the system, lights and ICE and “manual on” where the operator can manually turn on the ICE while the lights can remain in their automated mode controlled by the ICS. In another embodiment utilizing a 3-touch setup interface, the switch controlling the lights and ICE may have more than 3 positions allowing the operator variations on how to manage the way in which the lights, ICE and other system functions integrate, for example 4 or more positions. In another embodiment, a 4-Touch Setup Interface (4TSI) may be preferable in which case there is a separate switch to control the ICE functions and separate switch to control the lighting functions, both of which have switch positions for off, on and auto-on, the later allowing the ICS to manage the function of the ICE and/or the lights. In other embodiments the control for the lighting may turn on all lights at once or each light individually. In another embodiment the ICE function can be controlled by an ICE autostart controller allowing for off, on or manual run.

### Other Options

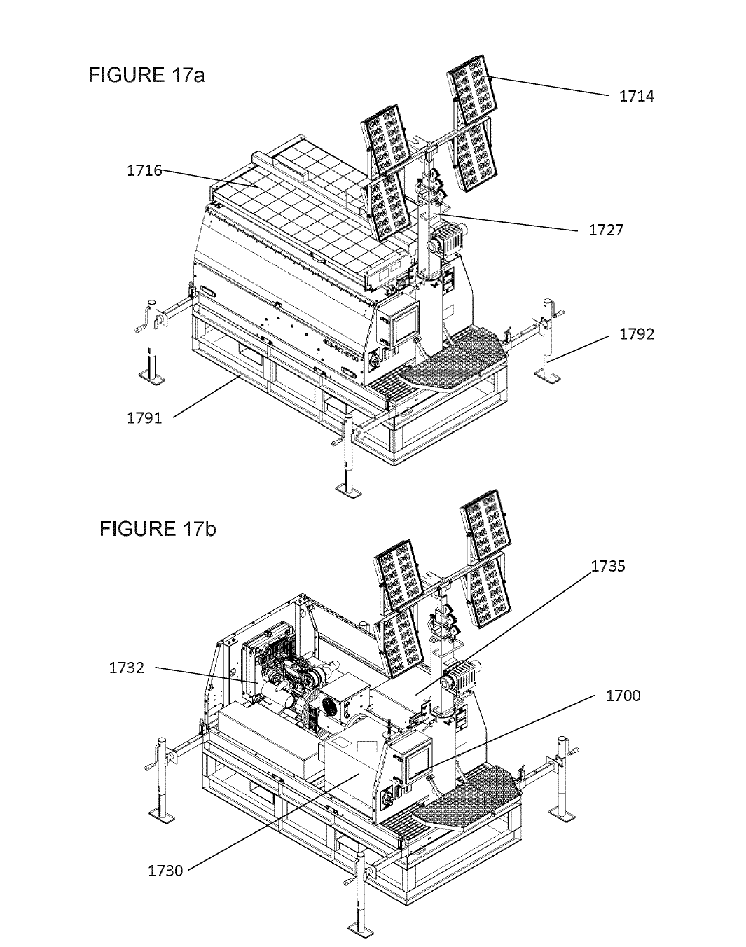

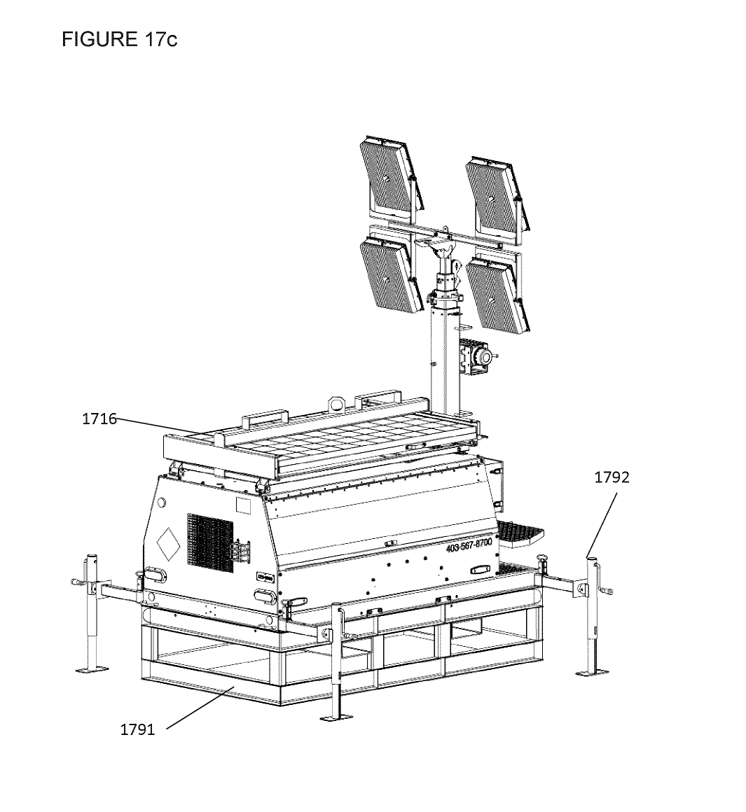

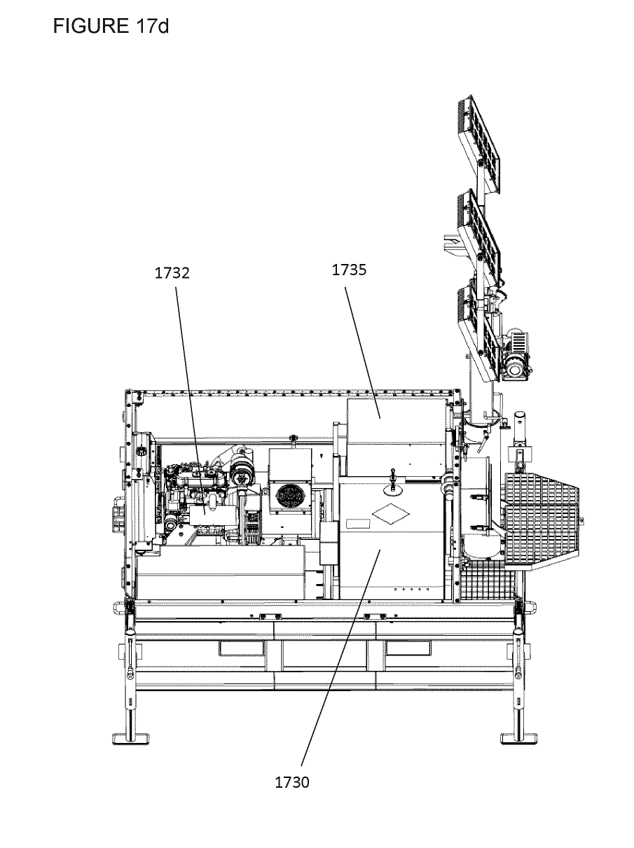

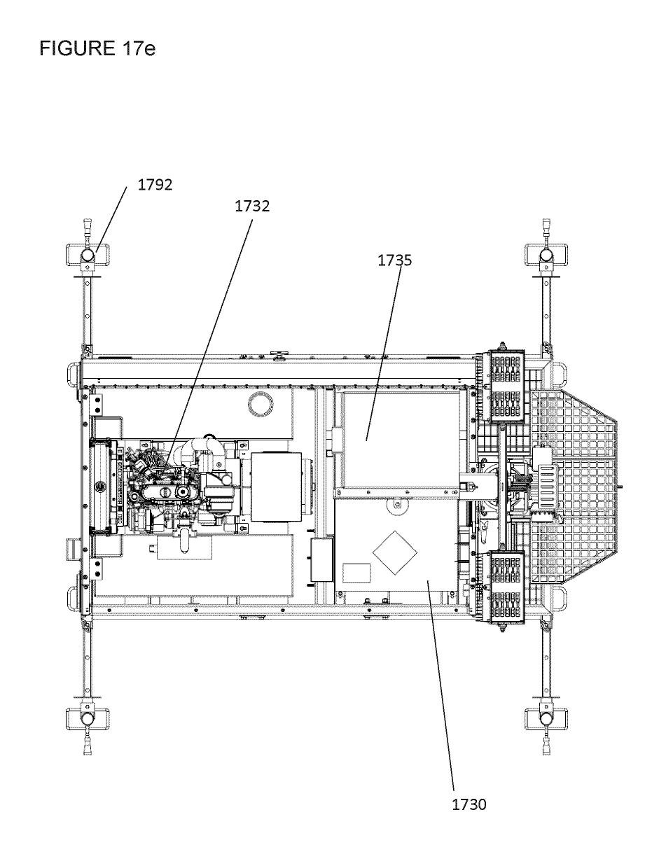

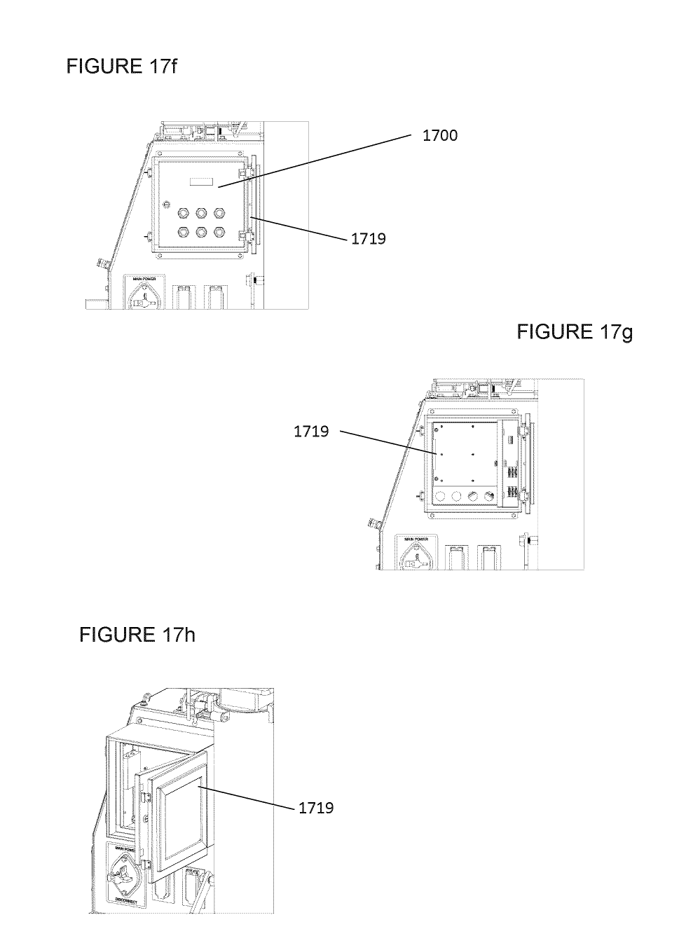

FIG. 17a-17e show a further embodiment of a portable hybrid lighting system. In this case, the portable hybrid lighting system is configured to rest on a skid 1791 which can be moved from location to location using, for example, a forklift. In this case, the LED lights 1714 are supported on a telescopic mast 1727. The mast 1727 is shown in FIGS. 17a-17e in the retracted position.

The power for the lighting system 1714 is, in this case, provided by an array of solar panels 1716 in conjunction with an internal combustion engine (ICE) 1732 having a direct current power generator configured to generate direct current directly from mechanical energy. The ICE in this case is an 8 kW Diesel engine.

Power can be stored in a battery storage system 1730, the battery storage system being operatively connected to the at least one light system and to the ICE and being configured: to store electrical power from the ICE direct current power generator, and to provide stored electrical power to the at least one light system.

In this case, the system comprises an AC/DC inverter 1735 for providing AC power output from DC power from the DC generator and/or battery storage system 1730.

When in use, the unit is configured to stand on four stabilizers (e.g. legs 1792), which can be independently adjusted to compensate for uneven or sloped ground.

FIGS. 17f-17h show a series of views of the control box 1719 for housing the control panel 1700. The control panel may correspond to that shown in FIG. 16. In particular, FIG. 17f shows the front door of the control box open to allow access to the control panel. FIGS. 17g and 17h show respective front and perspective views of the control panel pivoted away on hinges to allow access to the controller. The control panel may comprise one or more buttons or switches and/or a touchscreen.

The control panel may allow the user to control the controller and aspects of device operation. For example, as noted above, the control panel may be configured to allow the user to activate or deactivate the inverter to ensure the inverter is not consuming power when AC receptacles are not in use.

In other embodiments there may be no ICE activation switch for normal daily system use. In this embodiment the ICE is controlled by the control system to only turn on when the battery bank is at or below a specified lower SOC threshold. In this way, all power consumption needs, whether direct from the battery or its associated power sources or through an inverter, are drawn from the battery bank first, and it's only the battery bank SOC that can signal for ICE on. This embodiment ensures that all energy consumed by the system firstly uses energy stored in the battery bank from renewables or other stored power. In some embodiments an override switch (e.g. located on the control panel) may be provided to allow the ICE to be activated (e.g. for maintenance purposes).

The control box, in this case, houses a user interface operatively connected to the control system, PCB, circuit board and/or other control system. The user interface may have one or more of:
a. at least one mast switch for raising and lowering the mast;
b. at least one solar panel positioning switch wherein the solar panels are moved into their deployed position by activating a switch;
c. at least one solar panel wherein by raising the mast the solar panels are moved into their deployed position;
d. an activation switch operatively connected to the control system, the activation switch allowing the system to auto-manage itself without further manual operation from an operator, wherein the system is permitted to auto-manage and to activate and deactivate one or more of the following based on pre-determined operational parameters:
   i. the ICE
   ii. the lights
   iii. a battery heating system
   iv. an ICE heating system
   v. an inverter
   vi. permit use of receptacles via inverter;
e. an activation switch operatively connected to the control system, wherein the activation switch enables the system to
   i. auto-manage the ICE based on pre-determined operational parameters
   ii. deactivate the lights
   iii. permit use of receptacles via inverter;
f. an activation switch operatively connected to the control system, wherein the activation switch enables the system to
   i. auto-mange the ICE based on pre-determined operational parameters
   ii. activate the lights for a specified time period, the time period being determined by the operator or by pre-determined operational parameters
   iii. permit use of receptacles via inverter.

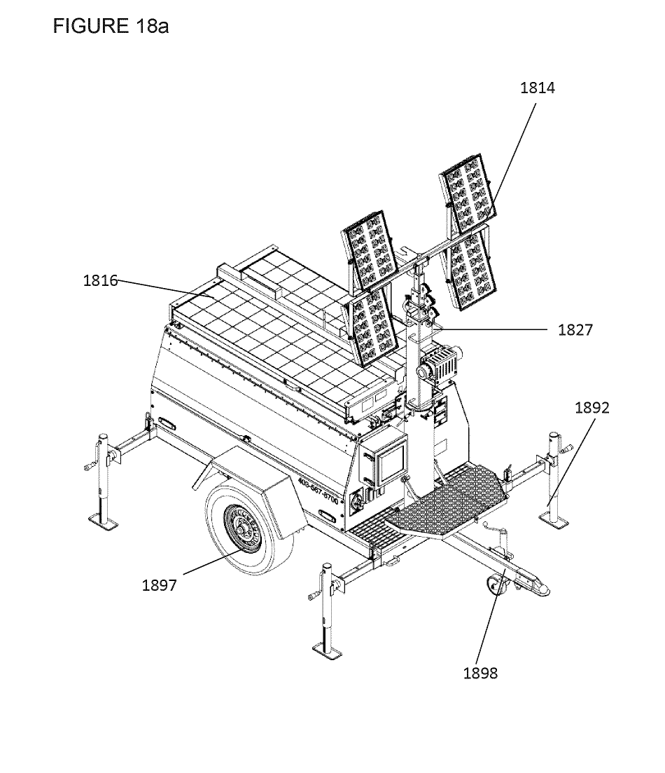

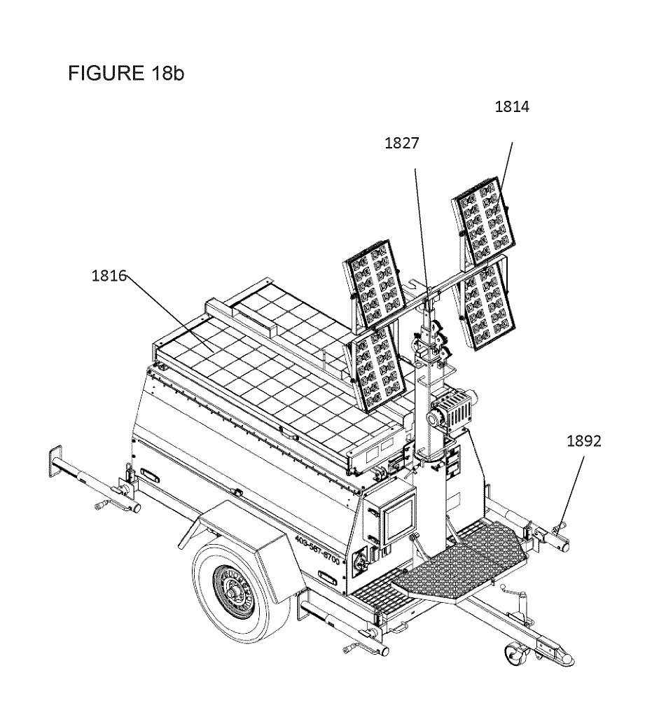

FIG. 18a-18b show an alternative embodiment which is similar to that of FIG. 17a except that the skid has been replaced with a trailer unit. That is, in this case, the body of the hybrid lighting system is configured to rest on a trailer axle with two wheels 1887 and can be towed via a tow-bar 1898.

Like the embodiment of FIG. 17a, When in use, the unit is configured to stand on four stabilizers (e.g. legs 1892), which can be independently adjusted to compensate for uneven or sloped ground. In FIG. 18a, the four stabilizers 1892 are shown in a vertical in-use configuration. For transport, the four stabilizers can be rotated to be horizontal to the ground for transport (as shown in FIG. 18b).

FIG. 19a-19c show a battery heating configuration. FIG. 19a shows a plate heater comprising a plate 1982 and a ceramic heater 1981 which can be placed between successive battery cells as shown in FIGS. 19b-c.

In this case, the battery storage system is housed within an insulated battery box 1985. It will be appreciated that the battery box case 1985 is shown in cut-away in FIGS. 19b-c and will substantially enclose the batteries. In this case, in addition to the batteries 1980 for supplying power to at least a lighting system, the battery box also contains a 12V starter battery 1933 for the ICE. The starter battery is also provided with a ceramic heater (50 W in this case) 1984 which is attached to a starter battery heater plate 1983 for distributing heat from the heater to the starter battery.

Although the present invention has been described and illustrated with respect to preferred embodiments and preferred uses thereof, it is not to be so limited since modifications and changes can be made therein which are within the full, intended scope of the invention as understood by those skilled in the art.

1-41. (canceled)

42. A portable hybrid lighting system comprising:
at least one light system operatively supported by a mast;
an internal combustion engine (ICE) having a direct current power generator configured to generate direct current directly from mechanical energy; and
a battery storage system, the battery storage system being operatively connected to the at least one light system and to the ICE and being configured: to store electrical power from the ICE direct current power generator, and to provide stored electrical power to the at least one light system.

43. The hybrid lighting system according to claim 42, wherein the hybrid lighting system comprises an AC/DC inverter configured:
to simultaneously receive direct current power from the connectors of a direct current power generator and the battery storage system; and
to provide an alternating current power supply from the received direct current power.

44. The hybrid lighting system according to claim 42, wherein the light system comprises one or more lights configured:
simultaneously to receive direct current power from the battery storage system and the direct current power generator; and
generate light directly from the received direct current power.

45. The hybrid lighting system according to claim 42, wherein the at least one light system is a light emitting diode (LED) light system.

46. The hybrid lighting system according to claim 42, wherein the portable hybrid lighting system is configured simultaneously to provide, from the battery storage system and the direct current power generator, direct current power to an external DC load.

47. The hybrid lighting system according to claim 42, wherein the battery storage system comprises a lithium ion battery configured to store electrical power from the ICE.

48. The hybrid lighting system according to claim 47, wherein the lithium ion battery comprises a lithium iron phosphate battery.

49. The hybrid lighting system according to claim 42, wherein the control system, DC generator and batteries are configured to enable the battery storage system to be charged at greater than the batter storage system 1 C rating.

50. The hybrid lighting system according to claim 42, wherein the battery storage system comprises thermally insulated batteries.

51. The hybrid lighting system according to claim 50, wherein the batteries are thermally insulated by expanded foam insulation.

52. The hybrid lighting system according to claim 50, wherein the battery storage system comprises a thermally insulating casing comprising one or more iron based electrical connectors configured to connect to corresponding copper connectors inside the casing and to corresponding copper connectors outside the casing to allow electricity to pass from the battery inside the casing to circuitry outside the casing.

53. The hybrid lighting system according to claim 42, further comprising a heating system operatively connected to the ICE and/or a control system, the heating system configured to heat the ICE when the ICE is off.

54. The hybrid lighting system according the claim 42, wherein the system comprises a battery heating system having one or more thermally conducting plates, the thermally conducting plates being configured: to be in contact with the batteries; and to receive and disperse heat from a heating element.

55. The hybrid lighting system according the claim 54, wherein the thermally conducting plates comprise thermal paste sandwiched between two metal plates.

56. The hybrid lighting system according to claim 42, further comprising a control system operatively connected to the direct current power generator and the battery storage system.

57. The hybrid lighting system as to claim 56, wherein the control system is configured to control, in response to determining that the ICE is not available, the power delivered to the lighting system based on one or more of the SOC and the voltage of the battery.

58. The hybrid lighting system as to claim 56, wherein the control system is configured to perform one or more of the following:
a) reduce the charging current when the State of Charge has exceeded a predetermined level; and
b) reduce the current taken from the battery when the State of Charge has dropped below a predetermined level.

59. The hybrid lighting system of claim 42, the hybrid lighting system comprising one or more DC-to-DC converters to convert the direct current power generated by the direct current power generator.

60. The hybrid lighting system of claim 42, wherein the hybrid lighting system comprises a control system configured to:
a) determine the global location; and
b) generate a lighting on-off schedule based on the determined global location.

61. The hybrid lighting system of claim 42, wherein the hybrid lighting system comprises a cell monitoring system configured to:
monitor the state of charge in an individual battery cell of a battery storage system;
open a contactor to prevent charging current passing to the individual cell based on one or more of the following:
if the cell voltage exceeds a predetermined high voltage cutoff; and
if the cell voltage goes below a predetermined low voltage cutoff.

62. The hybrid lighting system of claim 61, wherein the contactor is arranged in parallel with a diode configured to allow discharging current to flow from an individual cell or the battery bank whilst preventing charging current passing to the individual cell.

63. The hybrid lighting system of claim 42, wherein the system comprises a dimming controller, the diming controller configured to reduce the voltage to at least one light if at least one battery is below a threshold voltage and/or the ICE has failed to start.

64. The hybrid lighting system of claim 42, wherein the system comprises a signaling module configured to send signals to a user in response to a predetermined condition being satisfied.

65. An energy management system comprising:
at least one light system operatively supported by a mast;
an internal combustion engine (ICE) having a direct current power generator configured to generate direct current directly from mechanical energy; and
a battery storage system, the battery storage system being operatively connected to the at least one light system and to the ICE and being configured: to store electrical power from the ICE direct current power generator, and to provide stored electrical power to the at least one light system.
